(19) United States
(12) Patent Application Publication
(10) Pub. No.: US 2026/0090282 A1
(43) Pub. Date: Mar. 26, 2026

(54) MEMORY DEVICE

(71) Applicant: KIOXIA CORPORATION, Tokyo (JP)

(72) Inventors: Makoto ONIZAKI, Minato Tokyo (JP); Takeshi IWASAKI, Kuwana Mie (JP); Tadaomi DAIBOU, Yokkaichi Mie (JP); Katsuyoshi KOMATSU, Yokkaichi Mie (JP); Hikari TAJIMA, Mitaka Tokyo (JP); Kenta CHOKAWA, Yokohama Kanagawa (JP); Masakazu GOTO, Moriya Ibaraki (JP)

(73) Assignee: KIOXIA CORPORATION, Tokyo (JP)

(21) Appl. No.: 19/086,203

(22) Filed: Mar. 21, 2025

(30) Foreign Application Priority Data
Sep. 20, 2024 (JP) 2024-164011

(51) Int. Cl. H10N 50/85; G11C 5/06; G11C 11/16; G11C 13/00; H10B 61/00; H10B 63/00; H10N 50/10; H10N 70/00

(52) U.S. Cl. CPC H10N 50/85; G11C 5/063; G11C 11/161; H10B 61/10; H10B 63/20; H10N 50/10; H10N 70/8822; H10N 70/8825; H10N 70/8828; H10N 70/8833; G11C 11/1673; G11C 11/1675; G11C 13/004; G11C 2013/0045; G11C 2013/005; G11C 13/0069

(57) ABSTRACT

A memory device of embodiments includes a memory cell including a first conductive layer, a switching layer, a third conductive layer, a variable resistance layer, and a second conductive layer provided in this order. The switching layer contains an oxide of a first element, and a compound of a second element and a third element. The first element is Si, B, Ge, P, or As. The second element is Zn, Sn, Ga, In, or Bi. The third element is Te, S, or Se. A ratio of a sum of atomic concentrations of the first element and oxygen to a sum of atomic concentrations of the first element, the second element, the third element, and oxygen in the switching layer is equal to or more than 10%.

### CROSS-REFERENCE TO RELATED APPLICATION

This application is based upon and claims the benefit of priority from Japanese Patent Application No. 2024-164011, filed on Sep. 20, 2024, the entire contents of which are incorporated herein by reference.

### FIELD

Embodiments described herein relate generally to a memory device.

### BACKGROUND

As a large-capacity nonvolatile memory device, there is a cross-point type two-terminal memory device. In the cross-point type two-terminal memory device, scaling-down and high integration of memory cells are easy.

Each memory cell of the cross-point type two-terminal memory device has, for example, a variable resistance element and a switching element. Since the memory cell has a switching element, the current flowing through memory cells other than the selected memory cell is suppressed.

The switching element is required to have excellent characteristics, such as low leakage current, high on-current, and high reliability.

### BRIEF DESCRIPTION OF THE DRAWINGS

FIG. 1 is a block diagram of a memory device according to a first embodiment;

FIG. 2 is a schematic cross-sectional view of a memory cell in the memory device according to the first embodiment;

FIG. 3 is an explanatory diagram of the memory device according to the first embodiment;

FIG. 4 is an explanatory diagram of the current-voltage characteristic of a switching element in the first embodiment;

FIG. 5 is a schematic cross-sectional view of a memory cell in a memory device according to a first modification example of the first embodiment;

FIG. 6 is a schematic cross-sectional view of a memory cell in a memory device according to a second modification example of the first embodiment;

FIG. 7 is a schematic cross-sectional view of a memory cell in a memory device according to a third modification example of the first embodiment;

FIG. 8 is a schematic cross-sectional view of a memory cell in a memory device according to a second embodiment;

FIG. 9 is a schematic cross-sectional view of a memory cell in a memory device according to a modification example of the second embodiment;

FIG. 10 is a schematic cross-sectional view of a memory cell in a memory device according to a third embodiment;

FIG. 11 is a schematic cross-sectional view of a memory cell in a memory device according to a modification example of the third embodiment;

FIG. 12 is a schematic cross-sectional view of a memory cell in a memory device according to a fourth embodiment;

FIG. 13 is a schematic cross-sectional view of a memory cell in a memory device according to a fifth embodiment;

FIG. 14 is an explanatory diagram of the current-voltage characteristic of a memory element in the fifth embodiment;

FIG. 15 is an explanatory diagram of a first operation example of the memory operation in the memory device according to the fifth embodiment;

FIG. 16 is an explanatory diagram of a second operation example of the memory operation in the memory device according to the fifth embodiment;

FIG. 17 is an explanatory diagram of the current-voltage characteristic of a memory element according to a first modification example of the fifth embodiment;

FIG. 18 is an explanatory diagram of a third operation example of the memory operation in the memory device according to the first modification example of the fifth embodiment;

FIG. 19 is an explanatory diagram of a fourth operation example of the memory operation in the memory device according to the first modification example of the fifth embodiment;

FIG. 20 is an explanatory diagram of the current-voltage characteristic of a memory element according to a second modification example of the fifth embodiment;

FIG. 21 is an explanatory diagram of a fifth operation example of the memory operation in the memory device according to the second modification example of the fifth embodiment;

FIG. 22 is an explanatory diagram of a sixth operation example of the memory operation in the memory device according to the second modification example of the fifth embodiment;

FIG. 23 is an explanatory diagram of the current-voltage characteristic of a memory element according to a third modification example of the fifth embodiment;

FIG. 24 is an explanatory diagram of a seventh operation example of the memory operation in the memory device according to the third modification example of the fifth embodiment; and

FIG. 25 is an explanatory diagram of an eighth operation example of the memory operation in the memory device according to the third modification example of the fifth embodiment.

### DETAILED DESCRIPTION

A memory device of embodiments includes a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer. The switching layer contains an oxide of a first element, and a compound of a second element and a third element, the first element being at least one element selected from a group consisting of silicon (Si), boron (B), germanium (Ge), phosphorus (P), and arsenic (As), the second element being at least one element selected from a group consisting of zinc (Zn), tin (Sn), gallium (Ga), indium (In), and bismuth (Bi), and the third element being at least one element selected from a group consisting of tellurium (Te), sulfur (S), and selenium (Se). A first ratio of a sum of atomic concentrations of the first element and oxygen (O) to a sum of atomic concentrations of the first element, the second element, the third element, and oxygen (O) in the switching layer is equal to or more than 10%.

Hereinafter, embodiments will be described with reference to the diagrams. In addition, in the following description, the same or similar members and the like are denoted by the same reference numerals, and the description of the members and the like once described will be omitted as appropriate.

The qualitative analysis and quantitative analysis of the chemical composition forming the memory device in this specification can be performed by, for example, Rutherford backscattering spectroscopy (RBS), secondary ion mass spectroscopy (SIMS), energy dispersive X-ray spectroscopy (EDX), or electron energy loss spectroscopy (EELS). In addition, when measuring the thickness of each member forming the memory device, a distance between members, and the like, for example, a transmission electron microscope (TEM) can be used. In addition, for example, X-ray photoelectron spectroscopy (XPS), X-ray absorption fine structure (XAFS), Raman spectroscopy (Raman), or EELS can be used to identify the constituent materials of each member forming the memory device and to measure the presence ratio, bonding state, local structure (atomic distance, coordination number), and chemical state thereof.

### First Embodiment

A memory device according to a first embodiment includes a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer. The switching layer contains an oxide of a first element, and a compound of a second element and a third element, the first element being at least one element selected from a group consisting of silicon (Si), boron (B), germanium (Ge), phosphorus (P), and arsenic (As), the second element being at least one element selected from a group consisting of zinc (Zn), tin (Sn), gallium (Ga), indium (In), and bismuth (Bi), and the third element being at least one element selected from a group consisting of tellurium (Te), sulfur (S), and selenium (Se). A first ratio of a sum of atomic concentrations of the first element and oxygen (O) to a sum of atomic concentrations of the first element, the second element, the third element, and oxygen (O) in the switching layer is equal to or more than 10%.

In addition, the memory device according to the first embodiment further includes a plurality of first wirings and a plurality of second wirings crossing the plurality of first wirings. Then, the memory cell is provided in a region where one of the plurality of first wirings and one of the plurality of second wirings cross each other.

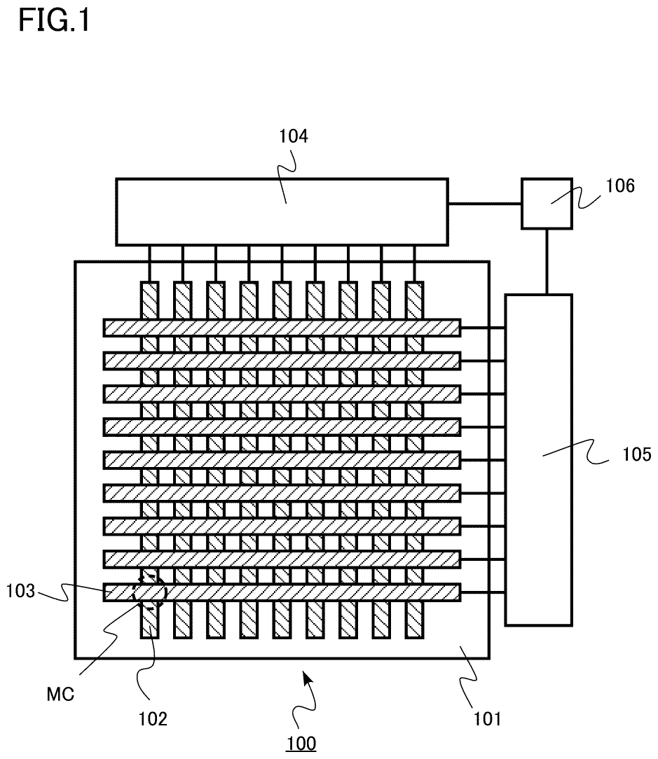

FIG. 1 is a block diagram of the memory device according to the first embodiment.

A memory cell array 100 in the memory device according to the first embodiment includes, for example, a plurality of word lines 102 and a plurality of bit lines 103 crossing the word lines 102 on a semiconductor substrate 101 with an insulating layer interposed therebetween. The bit lines 103 are provided in a layer above the word lines 102, for example. In addition, a first control circuit 104, a second control circuit 105, and a sense circuit 106 are provided as peripheral circuits around the memory cell array 100.

The word line 102 is an example of the first wiring. In addition, the bit line 103 is an example of the second wiring.

A plurality of memory cells MC are provided in regions where the word lines 102 and the bit lines 103 cross each other. The memory device according to the first embodiment is a two-terminal magnetoresistive memory having a cross-point structure.

Each of the plurality of word lines 102 is connected to the first control circuit 104. In addition, each of the plurality of bit lines 103 is connected to the second control circuit 105. The sense circuit 106 is connected to the first control circuit 104 and the second control circuit 105.

The first control circuit 104 and the second control circuit 105 have functions of selecting a desired memory cell MC, writing data to the memory cell MC, reading data from the memory cell MC, and deleting data from the memory cell MC, for example. When reading data, the data in the memory cell MC is read as the amount of current flowing between the word line 102 and the bit line 103 or as an electric potential change of the bit line 103. The sense circuit 106 has a function of determining the amount of current to determine the polarity of the data. For example, “0” and “1” of data are determined.

The first control circuit 104, the second control circuit 105, and the sense circuit 106 are electronic circuits using semiconductor devices formed on the semiconductor substrate 101, for example.

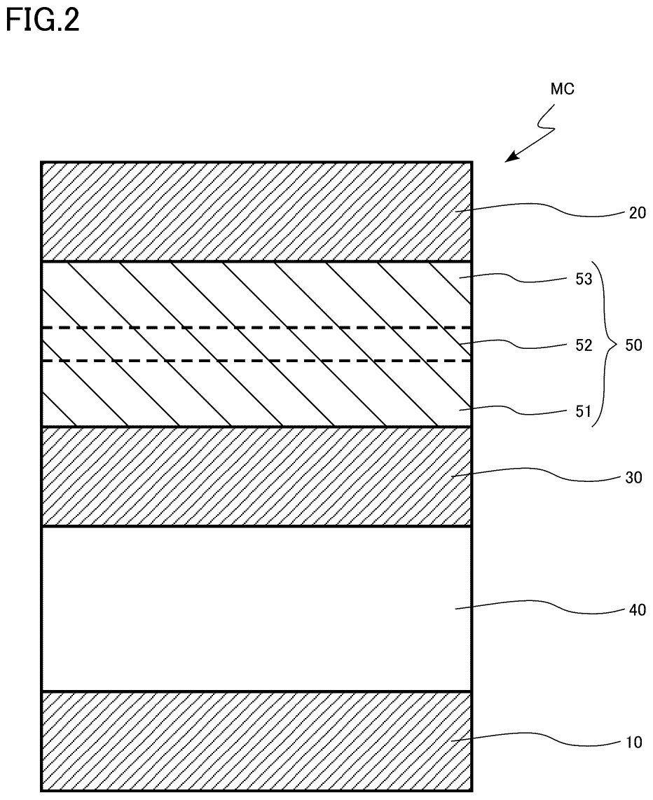

FIG. 2 is a schematic cross-sectional view of a memory cell in the memory device according to the first embodiment. FIG. 2 shows a cross section of one memory cell MC indicated by, for example, a dotted circle in the memory cell array 100 of FIG. 1.

As shown in FIG. 2, the memory cell MC includes a lower electrode 10, an upper electrode 20, an intermediate electrode 30, a switching layer 40, and a variable resistance layer 50. The variable resistance layer 50 includes a fixed layer 51, a tunnel layer 52, and a free layer 53.

The lower electrode 10 is an example of the first conductive layer. The upper electrode 20 is an example of the second conductive layer. The intermediate electrode 30 is an example of the third conductive layer.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The lower electrode 10 is connected to the word line 102. The lower electrode 10 is, for example, a metal. The lower electrode 10 contains, for example, at least one material selected from a group consisting of carbon, carbon nitride, tungsten, tungsten carbide, tungsten nitride, titanium, titanium nitride, tantalum, tantalum carbide, and tantalum nitride. The lower electrode 10 may be a part of the word line 102.

The upper electrode 20 is connected to the bit line 103. The upper electrode 20 is, for example, a metal. The upper electrode 20 contains, for example, at least one material selected from a group consisting of carbon, carbon nitride, tungsten, tungsten carbide, tungsten nitride, titanium, titanium nitride, tantalum, tantalum carbide, and tantalum nitride. The upper electrode 20 may be a part of the bit line 103.

The intermediate electrode 30 is provided between the lower electrode 10 and the upper electrode 20. The intermediate electrode 30 is, for example, a metal. The intermediate electrode 30 contains, for example, at least one material selected from a group consisting of carbon, carbon nitride, tungsten, tungsten carbide, tungsten nitride, titanium, titanium nitride, tantalum, tantalum carbide, and tantalum nitride.

The switching layer 40 is provided between the lower electrode 10 and the intermediate electrode 30. The thickness of the switching layer 40 in the first direction from the lower electrode 10 to the upper electrode 20 is, for example, equal to or more than 5 nm and equal to or less than 50 nm. It is preferable that the thickness of the switching layer 40 in the first direction from the lower electrode 10 to the upper electrode 20 is, for example, equal to or more than 5 nm and equal to or less than 20 nm.

The switching layer 40 has a function of suppressing an increase in half-select leakage current flowing through a half-selected cell. The switching layer has a nonlinear current-voltage characteristic that a current increases abruptly at a specific threshold voltage.

The switching layer 40 contains an oxide and a chalcogenide. The chalcogenide is a compound in which tellurium (Te), sulfur (S), or selenium (Se), which is a chalcogen element, is combined with other elements.

The switching layer 40 contains an oxide of a first element, which is at least one element selected from a group consisting of silicon (Si), boron (B), germanium (Ge), phosphorus (P), and arsenic (As). For example, the switching layer 40 contains at least one oxide selected from a group consisting of silicon oxide, boron oxide, germanium oxide, phosphorus oxide, and arsenic oxide.

The oxide of the first element, which is at least one element selected from a group consisting of silicon (Si), boron (B), germanium (Ge), phosphorus (P), and arsenic (As), is a so-called glass-forming oxide. The glass-forming oxide is an oxide that is easy to vitrify. For example, the glass-forming oxide is an oxide which has a relatively high crystallization temperature or glass transition temperature and whose amorphous state is relatively stable.

Whether or not the switching layer 40 contains an oxide of the first element can be determined by using, for example, X-ray photoelectron spectroscopy (XPS) or electron energy loss spectroscopy (EELS).

The switching layer 40 contains a chalcogenide that is a compound of a second element and a third element. The second element is at least one element selected from a group consisting of zinc (Zn), tin (Sn), gallium (Ga), indium (In), and bismuth (Bi). The third element is at least one element selected from a group consisting of tellurium (Te), sulfur (S), and selenium (Se). The switching layer 40 contains a chalcogenide of the second element.

The switching layer 40 contains, for example, at least one chalcogenide selected from a group consisting of zinc telluride, tin telluride, gallium telluride, indium telluride, bismuth telluride, zinc sulfide, tin sulfide, gallium sulfide, indium sulfide, bismuth sulfide, zinc selenide, tin selenide, gallium selenide, indium selenide, and bismuth selenide. The third element is more preferably tellurium (Te), and the switching layer 40 more preferably contains at least one chalcogenide selected from a group consisting of zinc telluride, tin telluride, gallium telluride, indium telluride, and bismuth telluride. Since telluride has a smaller bandgap than sulfide and selenide, the write voltage can be relatively reduced. Therefore, telluride has an advantage of being able to suppress fluctuations in half-select leakage current or fluctuations in characteristics such as fluctuations in on-current when writing is repeated.

Whether or not the switching layer 40 contains a chalcogenide of the second element can be determined by using, for example, X-ray absorption fine structure (XAFS), Raman spectroscopy (Raman), or electron energy loss spectroscopy (EELS).

The first ratio of the sum of the atomic concentrations of the first element and oxygen (O) to the sum of the atomic concentrations of the first element, the second element, the third element, and oxygen (O) in the switching layer 40 is, for example, equal to or more than 10% and equal to or less than 90%. For example, when the first element is silicon (Si), the second element is zinc (Zn), and the third element is tellurium (Te), the ratio ((Si+O)/(Si+Zn+Te+O)) of the sum of the atomic concentrations of silicon (Si) and oxygen (O) to the sum of the atomic concentrations of silicon (Si), zinc (Zn), tellurium (Te), and oxygen (O) in the switching layer 40 is, for example, equal to or more than 10% and equal to or less than 90%.

The oxide and chalcogenide described above are, for example, main components of the switching layer 40. The fact that the oxide and chalcogenide described above are the main components of the switching layer 40 means that there is no material having a higher mole fraction than the oxide or chalcogenide described above among the materials contained in the switching layer 40.

The sum of the atomic concentrations of the first element, the second element, the third element, and oxygen (O) in the switching layer 40 is, for example, equal to or more than 90% and equal to or less than 100%.

The switching layer 40 contains, for example, a mixture of the oxide and chalcogenide described above. The oxide and chalcogenide described above are present in the switching layer 40, for example, in a mixed state.

In the switching layer 40, the second ratio of the atomic concentration of the second element to the atomic concentration of the third element is, for example, equal to or more than 50% and equal to or less than 200%. For example, when the second element is zinc (Zn) and the third element is tellurium (Te), the second ratio (Zn/Te) of the atomic concentration of zinc (Zn) to the atomic concentration of tellurium (Te) in the switching layer 40 is, for example, equal to or more than 50% and equal to or less than 200%.

The switching layer 40 contains, for example, a fourth element that is at least one element selected from a group consisting of lithium (Li), sodium (Na), potassium (K), magnesium (Mg), calcium (Ca), barium (Ba), lead (Pb), aluminum (Al), vanadium (V), iron (Fe), and tungsten (W).

For example, the oxide of the first element containing the fourth element is also a so-called glass-forming oxide.

The atomic concentration of the fourth element contained in the switching layer 40 is, for example, lower than the atomic concentration of the first element. The atomic concentration of the fourth element contained in the switching layer 40 is, for example, equal to or more than 1% and equal to or less than 30%.

The switching layer 40 can be formed by using, for example, a sputtering method. The switching layer 40 containing the oxide of the first element and the chalcogenide of the second element can be formed by using, for example, a co-sputtering method using a target formed of the oxide of the first element and a target formed of the chalcogenide of the second element. In addition, the switching layer 40 can be formed by using, for example, a sputtering method using a target formed of a mixture of the oxide of the first element and the chalcogenide of the second element.

Since the oxide of the first element is a glass-forming oxide, for example, a vitrified target can be used as a target when forming the switching layer 40.

The variable resistance layer 50 is provided between the intermediate electrode 30 and the upper electrode 20. The variable resistance layer 50 includes the fixed layer 51, the tunnel layer 52, and the free layer 53. The variable resistance layer 50 includes a magnetic tunnel junction formed by the fixed layer 51, the tunnel layer 52, and the free layer 53.

The variable resistance layer 50 has a function of storing data by resistance change. The variable resistance layer 50 has, for example, a characteristic that its electrical resistance changes with the application of a predetermined voltage.

The fixed layer 51 is a ferromagnetic material. In the fixed layer 51, its magnetization direction does not change with respect to a predetermined write voltage, but is fixed in a specific direction.

The tunnel layer 52 is an insulator. Electrons pass through the tunnel layer 52 by the tunnel effect.

The free layer 53 is a ferromagnetic material. In the free layer 53, its magnetization direction changes with respect to a predetermined write voltage. The magnetization direction of the free layer 53 can be parallel to the magnetization direction of the fixed layer 51 or can be antiparallel to the magnetization direction of the fixed layer 51. For example, by applying a voltage between the intermediate electrode 30 and the upper electrode 20 so that a current flow between the intermediate electrode 30 and the upper electrode 20, the magnetization direction of the free layer 53 can be changed.

By changing the magnetization direction of the free layer 53, the electrical resistance of the variable resistance layer 50 changes. When the magnetization direction of the free layer 53 is antiparallel to the magnetization direction of the fixed layer 51, the electrical resistance becomes high. On the other hand, when the magnetization direction of the free layer 53 is parallel to the magnetization direction of the fixed layer 51, the electrical resistance becomes low. In addition, the arrangement of the fixed layer 51 and the free layer 53 may be reversed. That is, the intermediate electrode 30, the free layer 53, the tunnel layer 52, the fixed layer 51, and the upper electrode 20 may be stacked in this order.

Next, the function and effect of the memory device according to the first embodiment will be described.

In the memory device according to the first embodiment, as described above, the resistance of the variable resistance layer 50 is changed by changing the magnetization direction of the free layer 53. When the magnetization direction of the free layer 53 is antiparallel to the magnetization direction of the fixed layer 51, a high resistance state in which a current hardly flows is realized. On the other hand, when the magnetization direction of the free layer 53 is parallel to the magnetization direction of the fixed layer 51, a low resistance state in which a current flows easily is realized.

For example, the high resistance state of the variable resistance layer 50 is defined as data “1”, and the low resistance state of the variable resistance layer 50 is defined as data “0”. Since the memory cell MC can maintain different resistance states, it is possible to store 1-bit data of “0” and “1”. Writing to one memory cell MC is performed by applying a voltage between the bit line 103 and the word line 102 connected to the memory cell MC so that a current flows between the bit line 103 and the word line 102 connected to the memory cell MC.

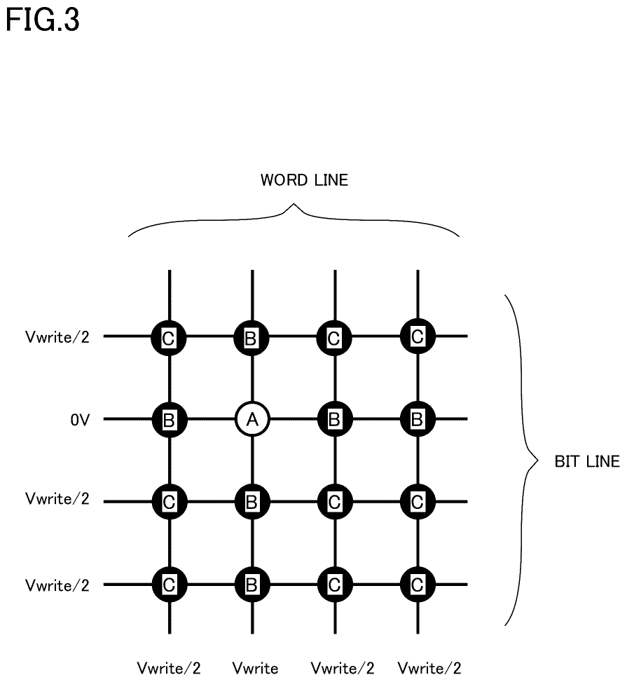

FIG. 3 is an explanatory diagram of the memory device according to the first embodiment. FIG. 3 shows a voltage applied to the memory cell MC when one memory cell MC in the memory cell array is selected for a write operation. The intersection of word lines and bit lines represents each memory cell MC.

The selected memory cell MC is a memory cell A (selected cell). A write voltage Vwrite is applied to the word line connected to the memory cell A. In addition, 0 V is applied to the bit line connected to the memory cell A.

Hereinafter, a case in which half the write voltage (Vwrite/2) is applied to the word lines and bit lines that are not connected to the memory cell A will be described as an example.

A voltage applied to memory cells C (unselected cells) connected to the word lines and bit lines that are not connected to the memory cell A is 0 V. That is, no voltage is applied.

On the other hand, half the write voltage Vwrite (Vwrite/2) is applied to memory cells B (half-selected cells) connected to the word lines or bit lines connected to the memory cell A. Therefore, a half-select leakage current flows through the memory cell B (half-selected cell).

In addition, as an application method other than those described above, a method may be used in which half the write voltage (Vwrite/2) is applied to the word line connected to the memory cell A, a negative voltage of half the write voltage (−Vwrite/2) is applied to the bit line, and 0 V is applied to the word line and the bit line that are not connected to the memory cell A.

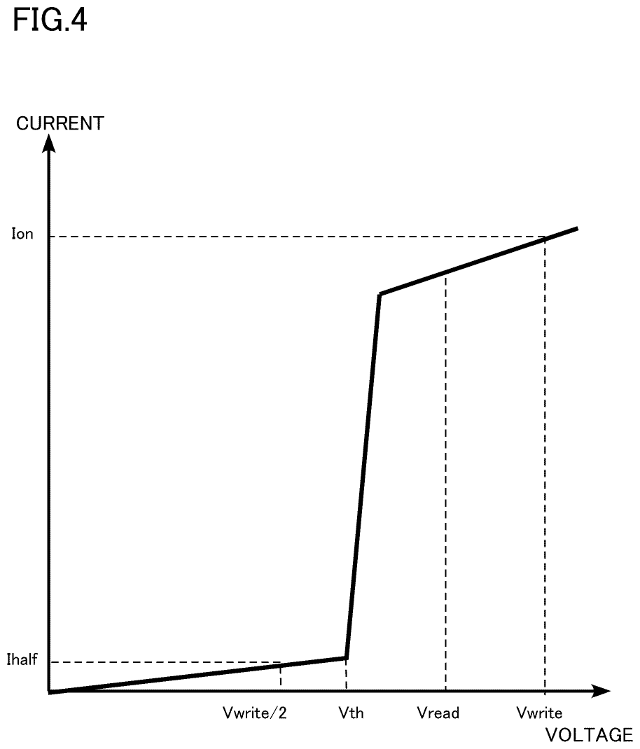

FIG. 4 is an explanatory diagram of the current-voltage characteristic of a switching element in the first embodiment. The horizontal axis indicates a voltage applied to the switching element, and the vertical axis indicates a current flowing through the switching element.

The switching element has a nonlinear current-voltage characteristic that the current increases abruptly at a threshold voltage Vth. The threshold voltage Vth is, for example, equal to or more than 0.5 V and equal to or less than 3 V.

The write voltage Vwrite is set such that the write voltage Vwrite is higher than the threshold voltage Vth and half the write voltage Vwrite (Vwrite/2) is lower than the threshold voltage Vth. The current flowing through the switching element when the write voltage Vwrite is applied is an on-current (Ion in FIG. 4). The current flowing through the switching element when half the write voltage Vwrite (Vwrite/2) is applied is a half-select leakage current (Ihalf in FIG. 4).

In addition, a read voltage Vread of the memory cell MC is set to a voltage higher than the threshold voltage Vth and lower than the write voltage Vwrite, as shown in FIG. 4, for example. Therefore, the half-select leakage current flowing through the half-selected cell can also be suppressed when reading the memory cell MC.

If the half-select leakage current is large, for example, the power consumption of the chip increases. In addition, for example, a voltage drop in the wiring increases and accordingly, a sufficiently high voltage is not applied to the selected cell. As a result, an operation for writing to the memory cell MC becomes unstable. In addition, if the on-current is small, for example, the current flowing through the selected cell is insufficient, resulting in insufficient writing to the memory cell MC. Therefore, as the current-voltage characteristic of the switching element, it is required to have both a low half-select leakage current and a high on-current.

In addition, high reliability is required for the current-voltage characteristic of the switching element. That is, it is required to realize high reliability by suppressing fluctuations in characteristics such as fluctuations in on-current or fluctuations in half-select leakage current when repeating data writing to the memory cell MC.

For example, as a switching element according to a comparative example, a switching element is considered in which a switching layer is formed of zirconium oxide, which is an oxide of zirconium (Zr), and zinc telluride, which is a chalcogenide of zinc (Zn) and tellurium (Te). The switching element according to the comparative example has a problem such as a high half-select leakage current or large fluctuations in characteristics when repeating data writing to the memory cell MC.

One reason why the above problem occurs in the switching element according to the comparative example is believed to be crystallization of zirconium oxide and zinc telluride. For example, due to heat generated when repeating data writing to the memory cell MC, the crystallization of zirconium oxide or zinc telluride progresses. As the crystallization of zirconium oxide or zinc telluride progresses, separation between zirconium oxide and zinc telluride progresses. As the separation between zirconium oxide and zinc telluride progresses, for example, film peeling occurs inside the switching layer or film peeling occurs between the switching layer and the electrodes, causing fluctuations in the characteristics of the switching element. For example, fluctuations in half-select leakage current or on-current of the switching element occur.

Another reason why the above problem occurs in the switching element according to the comparative example is believed to be that a chemical bond having a smaller band gap than zinc telluride is formed in the switching layer. When a chemical bond having a band gap significantly smaller than the band gap (Eg=2.25 eV) of the Zn—Te bond of zinc telluride is formed in the switching layer, this chemical bond becomes a leakage source, increasing the half-select leakage current of the switching element. In the comparative example, the chemical bond that becomes a leakage source is, for example, a Zr—Zr bond (Eg=0 eV), a Zn—Zn bond (Eg=0 eV), a Te—Te bond (Eg=0.34 eV), a Zr—Zn bond (Eg=0 eV), or a Zr—Te bond (Eg=0 eV).

The switching layer 40 of the switching element according to the first embodiment contains an oxide of the first element, which is at least one element selected from a group consisting of silicon (Si), boron (B), germanium (Ge), phosphorus (P), and arsenic (As). Since the switching layer 40 contains an oxide of the first element, it is possible to realize the suppression of fluctuations in characteristics and a low half-select leakage current.

One reason why the suppression of fluctuations in characteristics can be realized in the switching element according to the first embodiment is believed to be that the switching layer 40 contains an oxide of the first element, thereby suppressing crystallization of the oxide and chalcogenide of the first element.

The oxide of the first element is a glass-forming oxide. For example, the oxide of the first element is an oxide whose amorphous state is more stable than that of zirconium oxide. Therefore, for example, even when data writing to the memory cell MC is repeated, crystallization is difficult to occur as compared with the zirconium oxide. In addition, the atomic radius of the first element is smaller than the atomic radius of zirconium (Zr), for example. Therefore, it is believed that it is easier to fill gaps in the structure of the switching layer 40 than zirconium (Zr) and it is also possible to suppress crystallization of chalcogenides.

According to the switching element in the first embodiment, since the crystallization of the oxide and chalcogenide of the first element can be suppressed, it is possible to realize the suppression of fluctuations in characteristics.

Another reason why a low half-select leakage current can be realized in the switching element according to the first embodiment is believed to be that the switching layer 40 contains an oxide of the first element described above, which makes it possible to suppress the formation of a chemical bond with a small band gap in the switching layer. Hereinafter, a switching element in which the switching layer 40 is formed of silicon oxide, which is an oxide of silicon (Si), and zinc telluride, which is a chalcogenide of zinc (Zn) and tellurium (Te), will be considered as an example. That is, a case where the first element is silicon (Si), the second element is zinc (Zn), and the third element is tellurium (Te) will be considered as an example.

When the switching layer 40 is formed of silicon oxide and zinc telluride, the chemical bond that becomes a leakage source is, for example, a Zn—Zn bond (Eg=0 eV), a Te—Te bond (Eg=0.34 eV), or a Si—Zn bond (Eg=0 eV). For example, a Si—Si bond (Eg=1.12 eV) and a Si—Te bond (Eg=2.16 eV) have relatively large band gaps and accordingly, leakage is reduced.

First, when the switching layer 40 is formed of silicon oxide and zinc telluride, there are fewer types of chemical bonds that become leakage sources, compared with the comparative example. For example, in the comparative example, the Zr—Zr bond (Eg=0 eV) and the Zr—Te bond (Eg=0 eV) become leakage sources, whereas in the first embodiment, the corresponding Si—Si bond (Eg=1.12 eV) and Si—Te bond (Eg=2.16 eV) do not become leakage sources. Therefore, according to the switching element in the first embodiment, it is believed that a low half-select leakage current can be realized.

In addition, as a result of first-principles calculations by the inventors, it has become clear that in the first embodiment, the proportion of chemical bonds that become leakage sources in the switching layer 40 is lower than in the comparative example. In particular, when the first ratio of the sum of the atomic concentrations of silicon (Si) and oxygen (O) is equal to or more than 10%, the difference from the comparative example becomes noticeable. When the ratio of the sum of the atomic concentrations of silicon (Si) and oxygen (O) is equal to or more than 10%, the proportion of Zn—Zn bonds (Eg=0 eV) is particularly reduced, compared with the comparative example.

The proportion of Zn—Zn bonds (Eg=0 eV) decreases with an increase in the first ratio. From the viewpoint of reducing the proportion of Zn—Zn bonds (Eg=0 eV) and realizing a low half-select leakage current, the first ratio of the sum of the atomic concentrations of silicon (Si) and oxygen (O) is preferably equal to or more than 20%, and more preferably equal to or more than 40%.

In addition, as a result of first-principles calculations by the inventors, the sum of the proportions of all chemical bonds that become leakage sources, including Zn—Zn bonds (Eg=0 eV), decreases significantly when the first ratio is equal to or more than 55%. Therefore, from the viewpoint of reducing the proportion of chemical bonds that become leakage sources and realizing a low half-select leakage current, it is more preferable that the first ratio is equal to or more than 55%.

In addition, as a result of first-principles calculations by the inventors, it has become clear that in the first embodiment, when the first ratio of the sum of the atomic concentrations of silicon (Si) and oxygen (O) is equal to or more than 40%, the proportion of Zn—O bonds in the switching layer 40 becomes higher than that in the comparative example. This is believed to be due to the formation of Zn₂SiO₄ in the switching layer 40. It is believed that the formation of Zn₂SiO₄ in the switching layer 40 strengthens the bond between silicon oxide and zinc telluride, so that the separation between silicon oxide and zinc telluride is further suppressed.

Therefore, from the viewpoint of suppressing the separation between silicon oxide and zinc telluride and suppressing fluctuations in the characteristics of the switching element, it is preferable that the first ratio of the sum of the atomic concentrations of silicon (Si) and oxygen (O) is equal to or more than 40%.

As described above, in the first embodiment, the case where the first element is silicon (Si), the second element is zinc (Zn), and the third element is tellurium (Te) has been described as an example. However, the same function and effect can be obtained even if the first element, the second element, and the third element are other elements.

Therefore, the first ratio of the sum of the atomic concentrations of the first element and oxygen (O) to the sum of the atomic concentrations of the first element, the second element, the third element, and oxygen (O) in the switching layer 40 is preferably equal to or more than 20%, more preferably equal to or more than 40%, and even more preferably equal to or more than 55%.

In particular, from the viewpoint of realizing excellent switching characteristics, the first ratio of the sum of the atomic concentrations of the first element and oxygen (O) to the sum of the atomic concentrations of the first element, the second element, the third element, and oxygen (O) in the switching layer 40 is preferably equal to or less than 80%, and more preferably equal to or less than 70%.

In addition, from the viewpoint of reducing the proportion of chemical bonds that become leakage sources in the switching layer 40, the second ratio of the atomic concentration of the second element to the atomic concentration of the third element in the switching layer is preferably equal to or more than 50% and equal to or less than 200%, more preferably equal to or more than 80% and equal to or less than 140%, and even more preferably equal to or more than 97% and equal to or less than 103%.

In addition, in the memory device according to the first embodiment, since the oxide of the first element is a glass-forming oxide, a vitrified target can be used as a target used when forming the switching layer 40. The vitrified target can suppress the generation of particles as compared with a crystalline target. Therefore, according to the memory device according to the first embodiment, it is possible to realize a high manufacturing yield.

As described above, according to the first embodiment, it is possible to realize a switching element having excellent characteristics such as a low half-select leakage current and high reliability.

### First Modification Example

A memory device according to a first modification example of the first embodiment is different from the memory device according to the first embodiment in that a first conductive layer includes a first portion and a second portion and the first portion contains at least one element selected from hafnium (Hf), aluminum (Al), magnesium (Mg), zirconium (Zr), and titanium (Ti).

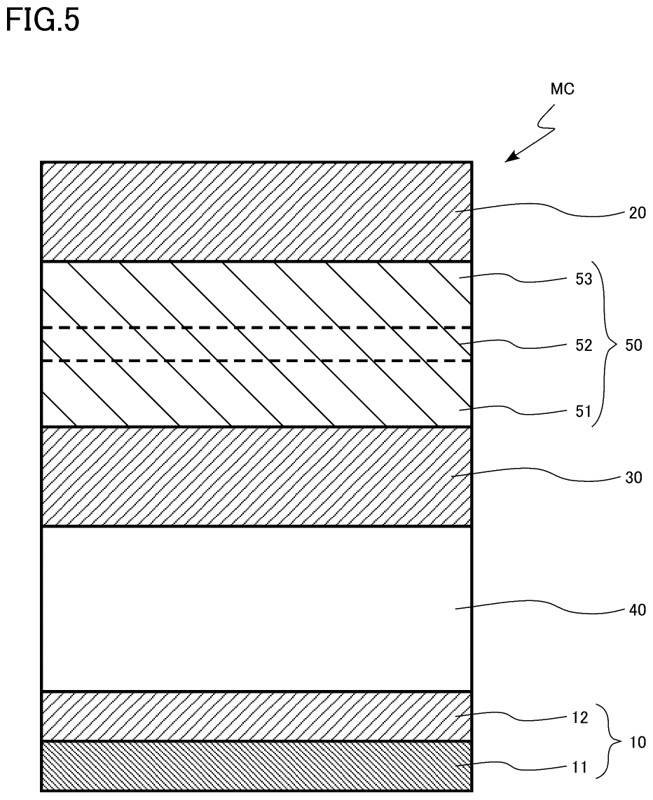

FIG. 5 is a schematic cross-sectional view of a memory cell in the memory device according to the first modification example of the first embodiment. FIG. 5 is a diagram corresponding to FIG. 2 in the first embodiment.

The lower electrode 10 includes a first portion 11 and a second portion 12. The second portion 12 is provided between the first portion 11 and the switching layer 40.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, aluminum magnesium boride, zirconium, zirconium boride, and titanium boride.

The second portion 12 contains, for example, at least one material selected from a group consisting of carbon, carbon nitride, tungsten, tungsten carbide, tungsten nitride, titanium, titanium nitride, tantalum, tantalum carbide, and tantalum nitride.

In the memory device according to the first modification example of the first embodiment, the first portion 11 of the lower electrode 10 contains at least one element selected from hafnium (Hf), aluminum (Al), magnesium (Mg), zirconium (Zr), and titanium (Ti), thereby suppressing the degradation of the characteristics of the variable resistance element. In addition, since the first portion 11 is not in contact with the switching layer 40, desorption of oxygen (O) from the switching layer 40 is suppressed and accordingly, degradation of the characteristics of the switching element is suppressed.

As described above, according to the first modification example of the first embodiment, as in the first embodiment, it is possible to realize a switching element having excellent characteristics such as a low half-select leakage current and high reliability.

### Second Modification Example

A memory device according to a second modification example of the first embodiment is different from the memory device according to the first embodiment in that a first conductive layer includes a first portion and a second portion, the first portion contains at least one element selected from hafnium (Hf), aluminum (Al), magnesium (Mg), zirconium (Zr), and titanium (Ti), a second conductive layer contains one element selected from hafnium (Hf), aluminum (Al), magnesium (Mg), zirconium (Zr), and titanium (Ti), a third conductive layer includes a third portion and a fourth portion, and the fourth portion contains at least one element selected from hafnium (Hf), aluminum (Al), magnesium (Mg), zirconium (Zr), and titanium (Ti).

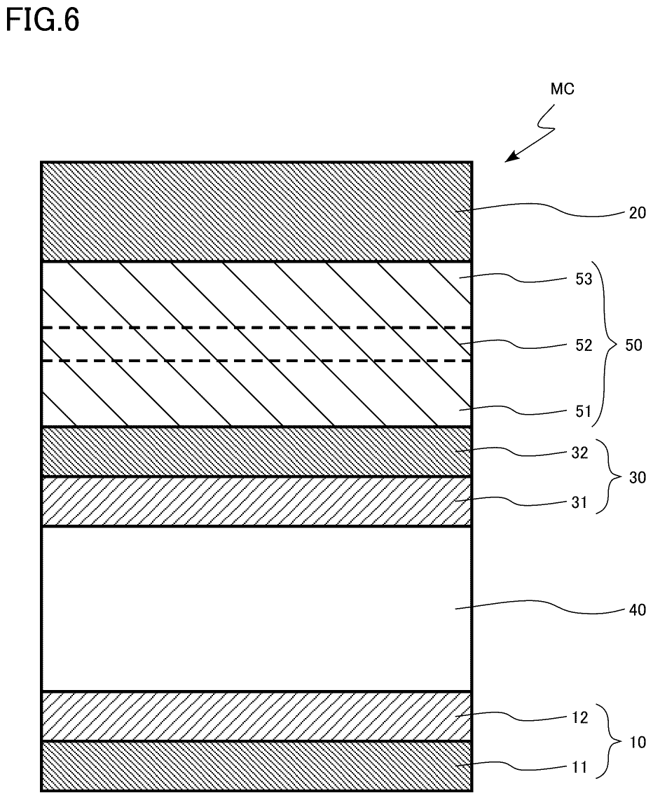

FIG. 6 is a schematic cross-sectional view of a memory cell in the memory device according to the second modification example of the first embodiment. FIG. 6 is a view corresponding to FIG. 2 in the first embodiment.

The lower electrode 10 includes a first portion 11 and a second portion 12. The second portion 12 is provided between the first portion 11 and the switching layer 40.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 contains, for example, at least one material selected from a group consisting of carbon, carbon nitride, tungsten, tungsten carbide, tungsten nitride, titanium, titanium nitride, tantalum, tantalum carbide, and tantalum nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 40.

The third portion 31 contains, for example, at least one material selected from a group consisting of carbon, carbon nitride, tungsten, tungsten carbide, tungsten nitride, titanium, titanium nitride, tantalum, tantalum carbide, and tantalum nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the second modification example of the first embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 40, desorption of oxygen (O) from the switching layer 40 is suppressed and accordingly, degradation of the characteristics of the switching element is suppressed.

As described above, according to the second modification example of the first embodiment, as in the first embodiment, it is possible to realize a switching element having excellent characteristics such as a low half-select leakage current and high reliability.

### Third Modification Example

A memory device according to a third modification example of the first embodiment is different from the memory device according to the first embodiment in that a first conductive layer includes a first portion, a second portion, and a fifth portion, the first portion contains at least one element selected from hafnium (Hf), aluminum (Al), magnesium (Mg), zirconium (Zr), and titanium (Ti), a second conductive layer contains at least one element selected from hafnium (Hf), aluminum (Al), magnesium (Mg), zirconium (Zr), and titanium (Ti), a third conductive layer includes a third portion and a fourth portion, and the fourth portion contains at least one element selected from hafnium (Hf), aluminum (Al), magnesium (Mg), zirconium (Zr), and titanium (Ti).

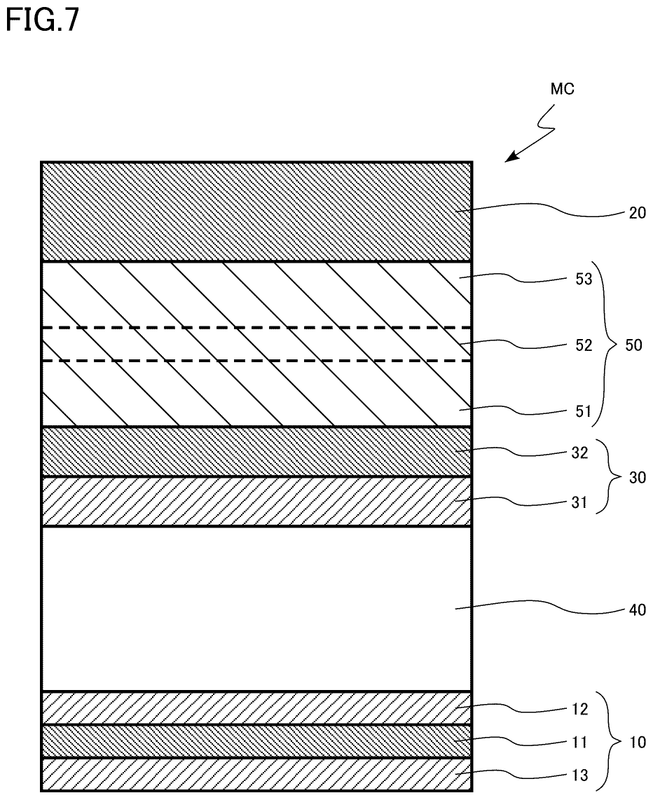

FIG. 7 is a schematic cross-sectional view of a memory cell in the memory device according to the third modification example of the first embodiment. FIG. 7 is a diagram corresponding to FIG. 2 in the first embodiment. The lower electrode 10 includes a first portion 11, a second portion 12, and a fifth portion 13. The second portion 12 is provided between the first portion 11 and the switching layer 40. The first portion 11 is provided between the fifth portion 13 and the second portion 12.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 and the fifth portion 13 contain, for example, at least one material selected from a group consisting of carbon, carbon nitride, tungsten, tungsten carbide, tungsten nitride, titanium, titanium nitride, tantalum, tantalum carbide, and tantalum nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 40.

The third portion 31 contains, for example, at least one material selected from a group consisting of carbon, carbon nitride, tungsten, tungsten carbide, tungsten nitride, titanium, titanium nitride, tantalum, tantalum carbide, and tantalum nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the third modification example of the first embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 40, desorption of oxygen (O) from the switching layer 40 is suppressed and accordingly, degradation of the characteristics of the switching element is suppressed.

As described above, according to the third modification example of the first embodiment, as in the first embodiment, it is possible to realize a switching element having excellent characteristics such as a low half-select leakage current and high reliability.

According to the first embodiment and its modification examples, it is possible to realize a switching element having excellent characteristics such as a low half-select leakage current and high reliability. Therefore, according to the first embodiment and its modification examples, it is possible to realize a memory device having a switching element with excellent characteristics.

### Second Embodiment

A memory device according to a second embodiment is different from the memory device according to the first embodiment in that a first conductive layer includes a first layer and a second layer provided between a switching layer and the first layer and in contact with the switching layer and the second layer contains tungsten, tungsten nitride, titanium, or titanium nitride. Hereinafter, the description of a part of the content overlapping the first embodiment may be omitted.

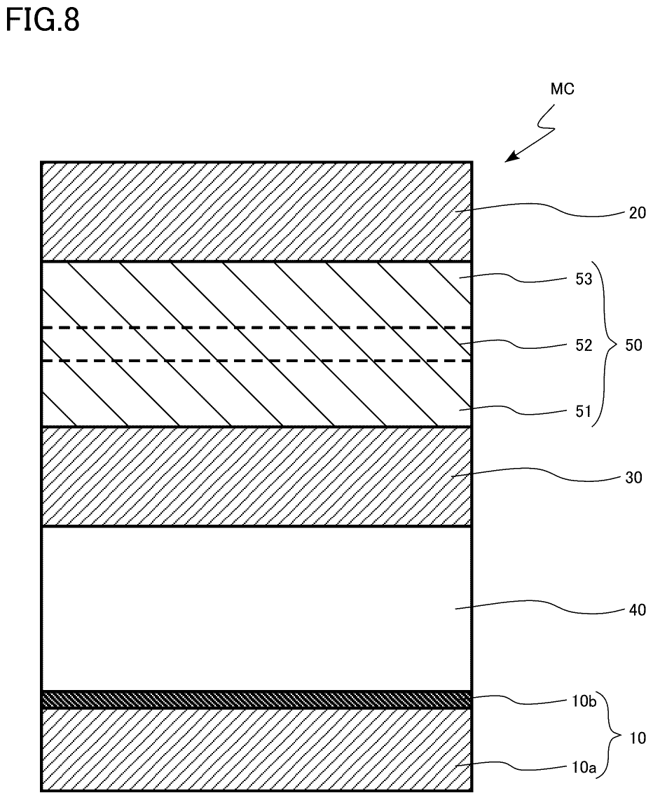

FIG. 8 is a schematic cross-sectional view of a memory cell in the memory device according to the second embodiment. FIG. 8 is a diagram corresponding to FIG. 2 in the first embodiment.

A lower electrode 10 includes a first layer 10a and a second layer 10b. The second layer 10b is provided between the first layer 10a and a switching layer 40. The second layer 10b is in contact with the switching layer 40.

The first layer 10a contains, for example, carbon, carbon nitride, or tungsten carbide. The first layer 10a is, for example, a carbon layer, a carbon nitride layer, or a tungsten carbide layer.

The second layer 10b contains tungsten, tungsten nitride, titanium, titanium nitride, tantalum, or tantalum nitride. The second layer 10b is, for example, a tungsten layer, a tungsten nitride layer, a titanium layer, a titanium nitride layer, a tantalum layer, or a tantalum nitride layer.

The thickness of the second layer 10b is, for example, equal to or more than 0.3 mm and equal to or less than 2 nm.

By providing the second layer 10b in the lower electrode 10, agglomeration of chalcogenide in the switching layer 40 can be suppressed. Therefore, for example, fluctuations in the characteristics of the switching element can be suppressed.

### Modification Example

A memory device according to a modification example of the second embodiment is different from the memory device according to the second embodiment in that a third conductive layer contains a first layer and a second layer provided between a switching layer and the first layer and in contact with the switching layer and the second layer contains tungsten, tungsten nitride, titanium, or titanium nitride.

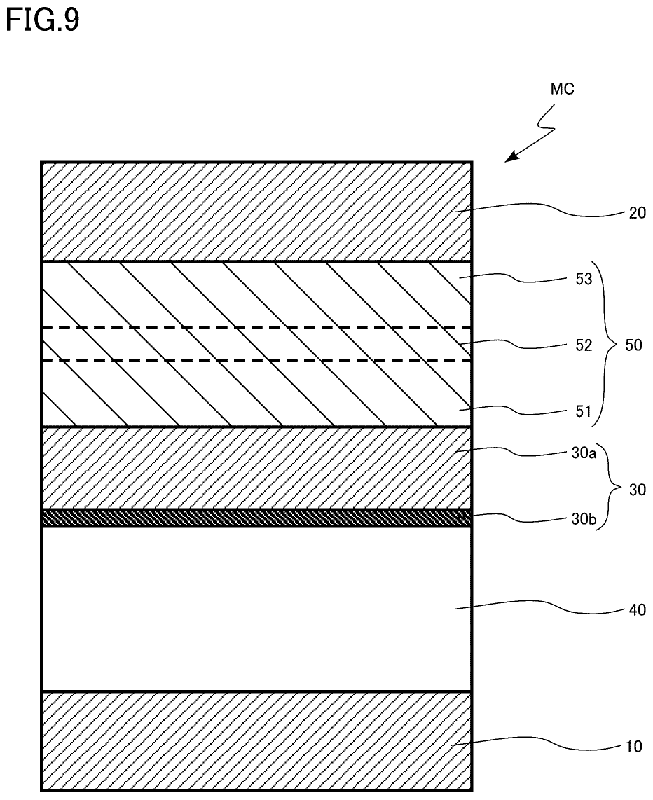

FIG. 9 is a schematic cross-sectional view of a memory cell in a memory device according to a modification example of the second embodiment. FIG. 9 is a diagram corresponding to FIG. 8 in the second embodiment.

An intermediate electrode 30 contains a first layer 30a and a second layer 30b. The second layer 30b is provided between the first layer 30a and a switching layer 40. The second layer 30b is in contact with the switching layer 40.

The first layer 30a contains, for example, carbon, carbon nitride, or tungsten carbide. The first layer 30a is, for example, a carbon layer, a carbon nitride layer, or a tungsten carbide layer.

The second layer 30b contains tungsten, tungsten nitride, titanium, titanium nitride, tantalum, or tantalum nitride. The second layer 30b is, for example, a tungsten layer, a tungsten nitride layer, a titanium layer, a titanium nitride layer, a tantalum layer, or a tantalum nitride layer.

The thickness of the second layer 30b is, for example, equal to or more than 0.3 nm and equal to or less than 2 nm.

By providing the second layer 30b in the intermediate electrode 30, agglomeration of chalcogenide in the switching layer 40 can be suppressed. Therefore, for example, fluctuations in the characteristics of the switching element can be suppressed.

In addition, as in the second embodiment, the lower electrode 10 may include the first layer 10a and the second layer 10b.

As described above, according to the second embodiment and its modification example, as in the first embodiment, it is possible to realize a switching element having excellent characteristics such as a low half-select leakage current and high reliability. Therefore, according to the second embodiment and its modification example, it is possible to realize a memory device having a switching element with excellent characteristics. In addition, according to the second embodiment and its modification example, fluctuations in the characteristics of the switching element can be further suppressed.

### Third Embodiment

A memory device according to a third embodiment is different from the memory device according to the first embodiment in that a switching layer includes a first region, a second region, and a third region in a cross section parallel to a first direction connecting a first conductive layer and a second conductive layer, the first region is provided between the second region and the third region in a second direction perpendicular to the first direction in the cross section, the first region contains or does not contain fluorine (F), the second region and the third region contain fluorine (F), and the atomic concentration of fluorine (F) in the second region and the third region is higher than the atomic concentration of fluorine in the first region. Hereinafter, the description of a part of the content overlapping the first embodiment may be omitted.

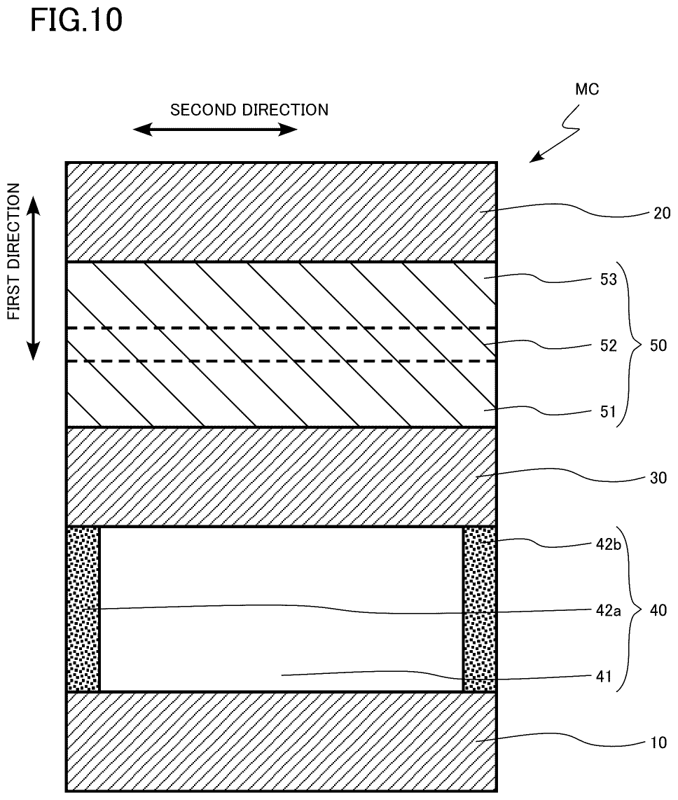

FIG. 10 is a schematic cross-sectional view of a memory cell in the memory device according to the third embodiment. FIG. 10 is a diagram corresponding to FIG. 2 in the first embodiment.

A switching layer 40 includes an inner region 41, a first sidewall region 42a, and a second sidewall region 42b. Hereinafter, the first sidewall region 42a and the second sidewall region 42b may be referred to as a sidewall region 42 individually or collectively.

In a cross section parallel to the first direction connecting the lower electrode 10 and the upper electrode 20, in the second direction perpendicular to the first direction, the inner region 41 is provided between the first sidewall region 42a and the second sidewall region 42b. The first sidewall region 42a and the second sidewall region 42b are provided, for example, between the lower electrode 10 and the intermediate electrode 30 in the first direction. The first sidewall region 42a and the second sidewall region 42b is in contact with, for example, the lower electrode 10 and the intermediate electrode 30, respectively, in the first direction.

The inner region 41 contains an oxide of the first element and a compound of the second element and the third element. The inner region 41 contains or does not contain fluorine (F).

The sidewall region 42 contains the second element and fluorine (F). The sidewall region 42 contains an oxide of the first element and contains or does not contain the third element.

The sidewall region 42 contains, for example, a compound of the second element and fluorine (F). For example, when the second element is zinc (Zn), the sidewall region 42 contains zinc fluoride (ZnF₂).

The atomic concentration of fluorine (F) in the sidewall region 42 is higher than the atomic concentration of fluorine (F) in the inner region 41. The atomic concentration of fluorine (F) in a first sidewall region 42a is higher than the atomic concentration of fluorine (F) in the inner region 41. The atomic concentration of fluorine (F) in the second sidewall region 42b is higher than the atomic concentration of fluorine (F) in the inner region 41. The atomic concentration of fluorine (F) in the sidewall region 42 is, for example, equal to or more than 2 times and equal to or less than 100 times the atomic concentration of fluorine (F) in the inner region 41.

The atomic concentration of the second element in the sidewall region 42 is, for example, higher than the atomic concentration of the second element in the inner region 41. The atomic concentration of the second element in the first sidewall region 42a is higher than the atomic concentration of the second element in the inner region 41. The atomic concentration of the second element in the second sidewall region 42b is higher than the atomic concentration of the second element in the inner region 41. The atomic concentration of the second element in the sidewall region 42 is, for example, equal to or more than 2 times and equal to or less than 100 times the atomic concentration of the second element in the inner region 41.

The thickness of each of the first sidewall region 42a and the second sidewall region 42b in the second direction is, for example, equal to or more than 0.5 nm and equal to or less than 5 nm.

The sidewall region 42 can be formed, for example, by using an etching gas containing fluorine (F) when patterning the switching layer 40 using a reactive ion etching method.

For example, when the switching layer 40 is patterned using a reactive ion etching method, if an etching gas containing chlorine (Cl) is used, the sidewall region 42 contains, for example, a compound of the second element and chlorine (Cl). For example, when the second element is zinc (Zn), the sidewall region 42 contains zinc chloride (ZnCl₂).

For example, a compound of the second element and fluorine (F) has a higher melting point and a larger band gap than a compound of the second element and chlorine (Cl). Therefore, the compound of the second element and fluorine (F) has high stability and high insulating properties.

Since the memory device according to the third embodiment includes the sidewall region 42, for example, the characteristics of the switching element are stabilized.

### Modification Example

A memory device according to a modification example of the third embodiment is different from the memory device according to the third embodiment in that the atomic concentration of the second element in the second region and the third region is lower than the atomic concentration of the second element in the first region and the atomic concentration of the third element in the second region and the third region is lower than the atomic concentration of the third element in the first region.

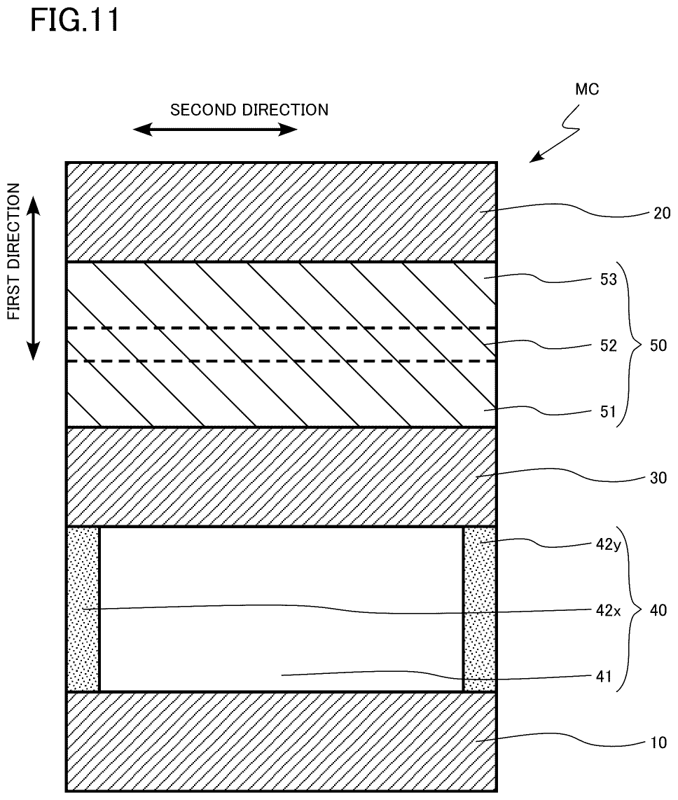

FIG. 11 is a schematic cross-sectional view of a memory cell in the memory device according to the modification example of the third embodiment. FIG. 11 is a diagram corresponding to FIG. 10 in the third embodiment.

A switching layer 40 contains an inner region 41, a first sidewall region 42x, and a second sidewall region 42y. Hereinafter, the first sidewall region 42x and the second sidewall region 42y may be referred to as a sidewall region 42 individually or collectively.

The inner region 41 contains an oxide of the first element and a compound of the second element and a third element.

The sidewall region 42 contains an oxide of the first element, the second element, and the third element.

The atomic concentration of the second element in the sidewall region 42 is lower than the atomic concentration of the second element in the inner region 41. The atomic concentration of the second element in the first sidewall region 42x is lower than the atomic concentration of the second element in the inner region 41. The atomic concentration of the second element in the second sidewall region 42y is lower than the atomic concentration of the second element in the inner region 41. The atomic concentration of the second element in the sidewall region 42 is, for example, equal to or more than one-hundredth and equal to or less than one-half of the atomic concentration of the second element in the inner region 41.

The atomic concentration of the third element in the sidewall region 42 is lower than the atomic concentration of the third element in the inner region 41. The atomic concentration of the third element in the first sidewall region 42x is lower than the atomic concentration of the third element in the inner region 41. The atomic concentration of the third element in the second sidewall region 42y is lower than the atomic concentration of the third element in the inner region 41. The atomic concentration of the third element in the sidewall region 42 is, for example, equal to or more than one-hundredth and equal to or less than one-half of the atomic concentration of the third element in the inner region 41.

The atomic concentration of the first element in the sidewall region 42 is, for example, higher than the atomic concentration of the first element in the inner region 41. The atomic concentration of oxygen (O) in the sidewall region 42 is, for example, higher than the atomic concentration of oxygen (O) in the inner region 41.

The thickness of each of the first sidewall region 42x and the second sidewall region 42y in the second direction is, for example, equal to or more than 0.5 nm and equal to or less than 5 nm.

For example, an etching gas containing fluorine (F) is used when patterning the switching layer 40 using a reactive ion etching method, as in the third embodiment. Thereafter, the compound of the second element and fluorine (F) formed on the side surface of the switching layer 40 is removed by using, for example, a wet etching method, thereby forming the sidewall region 42.

For example, the sidewall region 42 has lower concentrations of the second element and the third element than the inner region 41, so that the sidewall region 42 has higher material stability than the inner region 41.

Since the memory device according to the modification example of the third embodiment includes the sidewall region 42, the characteristics of the switching element are stabilized.

As described above, according to the third embodiment and its modification example, as in the first embodiment, it is possible to realize a switching element having excellent characteristics such as a low half-select leakage current and high reliability. Therefore, according to the third embodiment and its modification example, it is possible to realize a memory device having a switching element with excellent characteristics. In addition, according to the third embodiment and its modification example, the characteristics of the switching element is further stabilized.

### Fourth Embodiment

A memory device according to a fourth embodiment is different from the memory device according to the first embodiment in that the memory device according to the fourth embodiment is a resistive memory (ReRAM). Hereinafter, the description of a part of the content overlapping the first embodiment will be omitted.

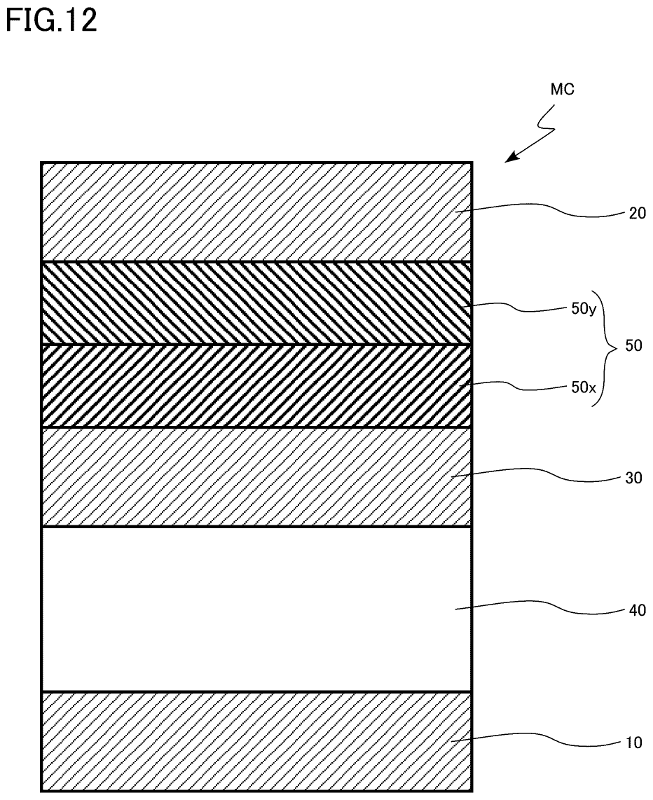

FIG. 12 is a schematic cross-sectional view of a memory cell in the memory device according to the fourth embodiment. FIG. 12 shows a cross section of one memory cell MC indicated by, for example, a dotted circle in the memory cell array 100 of FIG. 1.

As shown in FIG. 12, the memory cell MC includes a lower electrode 10, an upper electrode 20, an intermediate electrode 30, a switching layer 40, and a variable resistance layer 50. The variable resistance layer 50 includes a high resistance layer 50x and a low resistance layer 50y.

The lower electrode 10 is an example of the first conductive layer. The upper electrode 20 is an example of the second conductive layer. The intermediate electrode 30 is an example of the third conductive layer.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The configuration of the switching layer 40 is similar to that in the memory device according to the first to third embodiments.

The variable resistance layer 50 includes the high resistance layer 50x and the low resistance layer 50y.

The high resistance layer 50x is, for example, a metal oxide. The high resistance layer 50x is, for example, an aluminum oxide, a hafnium oxide, a zirconium oxide, a tantalum oxide, or a niobium oxide.

The low resistance layer 50y is, for example, a metal oxide. The low resistance layer 50y is, for example, a titanium oxide, a niobium oxide, a tantalum oxide, or a tungsten oxide.

The variable resistance layer 50 has a function of storing data by resistance change. The variable resistance layer 50 has, for example, a characteristic that its electrical resistance changes with the application of a predetermined voltage.

By applying a voltage to the variable resistance layer 50, the variable resistance layer 50 changes from a high resistance state to a low resistance state or from a low resistance state to a high resistance state. By applying a voltage to the variable resistance layer 50, oxygen ions move between the high resistance layer 50x and the low resistance layer 50y, so that the amount of oxygen deficiency (the amount of oxygen vacancies) in the low resistance layer 50y changes. The electrical conductivity of the variable resistance layer 50 changes according to the amount of oxygen deficiency in the low resistance layer 50y. The low resistance layer 50y is a so-called vacancy modulated conductive oxide.

For example, the high resistance state is defined as data “1”, and the low resistance state is defined as data “0”. The memory cell MC can store 1-bit data of “0” and “1”.

As described above, according to the memory device according to the fourth embodiment, as in the first embodiment, it is possible to realize a switching element having excellent characteristics such as a low half-select leakage current and high reliability. Therefore, according to the fourth embodiment, it is possible to realize a memory device having a switching element with excellent characteristics.

### Fifth Embodiment

A memory device according to a fifth embodiment includes a memory cell including a first conductive layer, a second conductive layer, and a memory layer provided between the first conductive layer and the second conductive layer. The memory layer contains an oxide of a first element and a compound of a second element and a third element, the first element being at least one element selected from a group consisting of silicon (Si), boron (B), germanium (Ge), phosphorus (P), and arsenic (As), the second element being at least one element selected from a group consisting of zinc (Zn), tin (Sn), gallium (Ga), indium (In), and bismuth (Bi), and the third element being at least one element selected from a group consisting of tellurium (Te), sulfur (S), and selenium (Se). A first ratio of a sum of atomic concentrations of the first element and oxygen (O) to a sum of atomic concentrations of the first element, the second element, the third element, and oxygen (O) in the switching layer is equal to or more than 10%.

In addition, the memory device according to the fifth embodiment further includes a plurality of first wirings and a plurality of second wirings crossing the plurality of first wirings. Then, the memory cell is provided in a region where one of the plurality of first wirings crosses one of the plurality of second wirings.

The memory device according to the fifth embodiment is different from the memory device according to the first to fourth embodiments in that the memory cell does not include a third conductive layer and a variable resistance layer and includes a configuration similar to the switching layer in the first to fourth embodiments as a memory layer. Hereinafter, the description of a part of the content overlapping the first to fourth embodiments will be omitted.

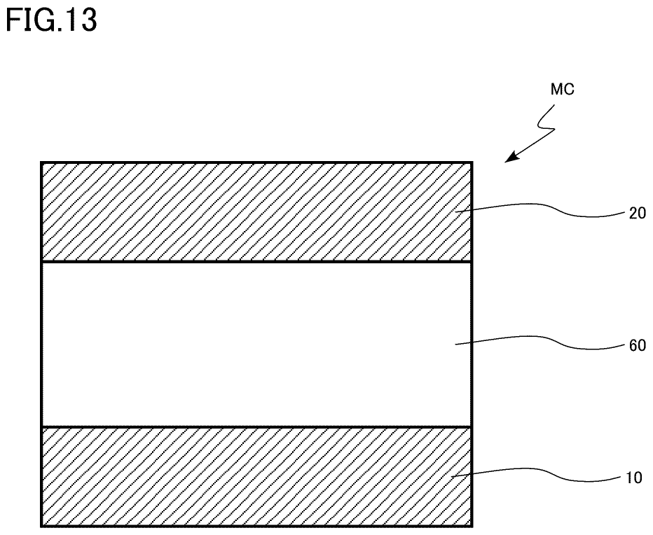

FIG. 13 is a schematic cross-sectional view of a memory cell in the memory device according to the fifth embodiment. FIG. 13 shows a cross section of one memory cell MC indicated by, for example, a dotted circle in the memory cell array 100 of FIG. 1.

As shown in FIG. 13, the memory cell MC includes a lower electrode 10, an upper electrode 20, and a memory layer 60.

The lower electrode 10 is an example of the first conductive layer. The upper electrode 20 is an example of the second conductive layer.

The lower electrode 10, the memory layer 60, and the upper electrode 20 form a memory element of the memory cell MC. The memory element of the memory cell MC has a switching function and an information storage function.

The memory layer 60 has a configuration similar to that of the switching layer 40 in the first to fourth embodiments. That is, the memory layer 60 contains an oxide of the first element, which is at least one element selected from a group consisting of silicon (Si), boron (B), germanium (Ge), phosphorus (P), and arsenic (As), a compound of the second element, which is at least one element selected from a group consisting of zinc (Zn), tin (Sn), gallium (Ga), indium (In), and bismuth (Bi), and the third element, which is at least one element selected from a group consisting of tellurium (Te), sulfur (S), and selenium (Se), and the first ratio of the sum of the atomic concentrations of the first element and oxygen (O) to the sum of the atomic concentrations of the first element, the second element, the third element, and oxygen (O) in the switching layer is equal to or more than 10%.

The memory layer 60 has a nonlinear current-voltage characteristic in which a current increases abruptly at a specific threshold voltage. In addition, the memory layer 60 has a characteristic that the threshold voltage changes with the application of a predetermined voltage. The memory layer 60 has a characteristic that its electrical resistance changes with the application of a predetermined voltage. In the fifth embodiment, the high resistance state is a state in which the resistance of the memory layer 60 is relatively high at the read voltage. In addition, in the fifth embodiment, the low resistance state is a state in which the resistance of the memory layer 60 is relatively low at the read voltage.

The memory layer 60 has a function of suppressing an increase in half-select leakage current flowing through the half-selected cell. In addition, the memory layer 60 has a function of storing data by resistance change. The memory layer 60 is a single layer and realizes the function of the switching layer 40 and the function of the variable resistance layer 50 in the first to fourth embodiments.

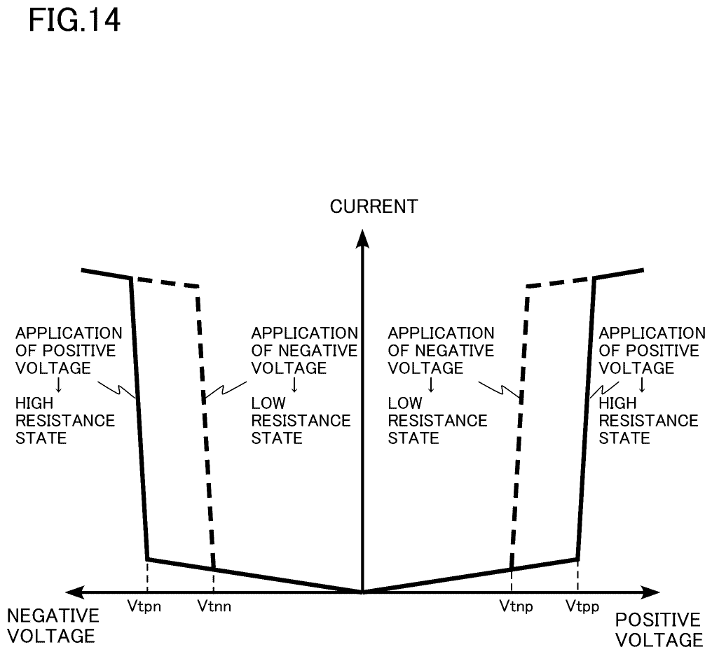

FIG. 14 is an explanatory diagram of the current-voltage characteristic of a memory element according to the fifth embodiment. The horizontal axis indicates a voltage applied to the memory element, and the vertical axis indicates a current flowing through the memory element. In FIG. 14, the horizontal axis indicates a voltage applied to the upper electrode 20 with the electric potential of the lower electrode 10 as a reference. FIG. 14 shows the current-voltage characteristic of the memory layer 60 in the fifth embodiment. FIG. 14 shows the current-voltage characteristic of the memory cell MC in the fifth embodiment.

The memory element according to the fifth embodiment shows different current-voltage characteristics when a predetermined positive voltage is applied to the upper electrode 20 and when a predetermined negative voltage is applied to the upper electrode 20. In FIG. 14, the solid line indicates a current-voltage characteristic when a predetermined positive voltage is applied to the upper electrode 20, and the dotted line indicates a current-voltage characteristic when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is lower than the second negative voltage side threshold voltage Vtnn.

The memory element according to the fifth embodiment can have a high resistance state and a low resistance state on both the positive voltage side and the negative voltage side. When a predetermined positive voltage is applied to the upper electrode 20, a high resistance state is realized on both the positive voltage side and the negative voltage side. On the other hand, when a predetermined negative voltage is applied to the upper electrode 20, a low resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

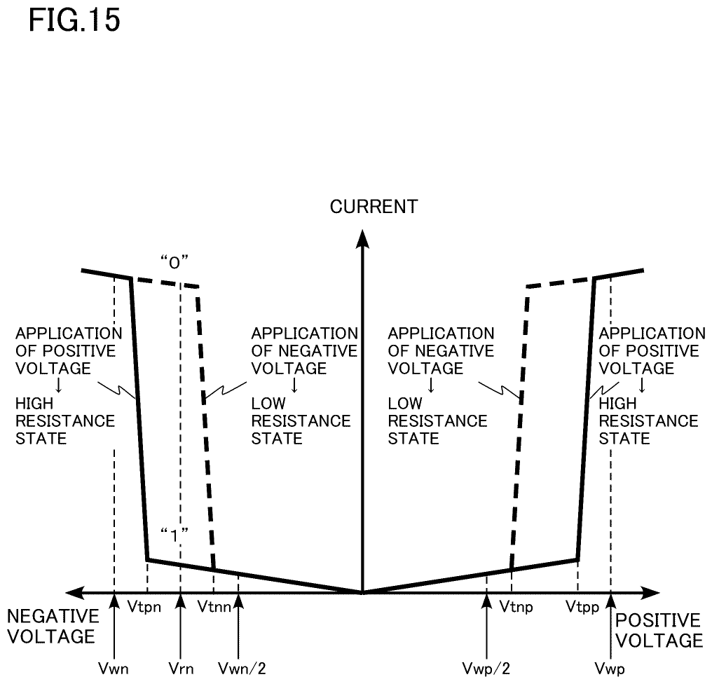

FIG. 15 is an explanatory diagram of a first operation example of the memory operation in the memory device according to the fifth embodiment. FIG. 15 shows a positive side write voltage Vwp, half the positive side write voltage Vwp (Vwp/2), a negative side write voltage Vwn, half the negative side write voltage Vwn (Vwn/2), and a negative side read voltage Vrn when performing a memory operation.

In the first operation example, the high resistance state and the low resistance state on the negative voltage side are used for the memory operation. In the first operation example, the negative side read voltage Vrn is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the negative voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the negative voltage side, and data “0” is written to the selected cell.

In the first operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the first operation example, regardless of whether the data of the selected cell is data “1” or data “0”, the application of the negative side read voltage Vrn does not destroy the data. In other words, in the case of the first operation example, non-destructive reading is possible regardless of whether the data of the selected cell is data “1” or data “0”.

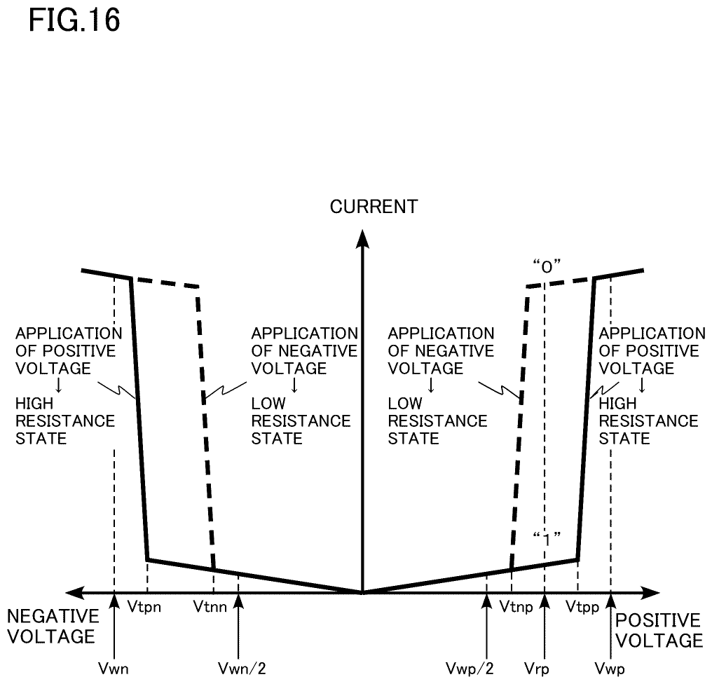

FIG. 16 is an explanatory diagram of a second operation example of the memory operation in the memory device according to the fifth embodiment. FIG. 16 shows a positive side write voltage Vwp, half the positive side write voltage Vwp (Vwp/2), a negative side write voltage Vwn, half the negative side write voltage Vwn (Vwn/2), and a positive side read voltage Vrp when performing a memory operation.

In the second operation example, the high resistance state and the low resistance state on the positive voltage side are used for the memory operation. In the second operation example, the positive side read voltage Vrp is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the positive voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the positive voltage side, and data “0” is written to the selected cell.

In the second operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the second operation example, when the data of the selected cell is data “1”, the application of the positive side read voltage Vrp does not destroy the data. In other words, in the case of the second operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the second operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

### First Modification Example

A memory device according to a first modification example of the fifth embodiment is different from the memory device according to the fifth embodiment in that the current-voltage characteristics of the memory elements are different.

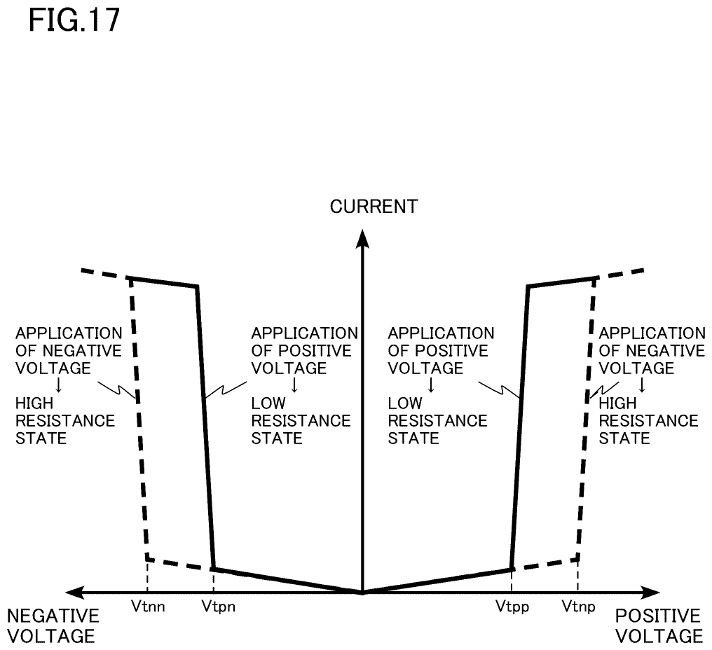

FIG. 17 is an explanatory diagram of the current-voltage characteristic of a memory element according to the first modification example of the fifth embodiment. The horizontal axis indicates a voltage applied to the memory element, and the vertical axis indicates a current flowing through the memory element. In FIG. 17, the horizontal axis indicates a voltage applied to the upper electrode 20 with the electric potential of the lower electrode 10 as a reference. FIG. 17 shows the current-voltage characteristic of the memory layer 60 in the first modification example of the fifth embodiment. FIG. 17 shows the current-voltage characteristic of the memory cell MC in the first modification example of the fifth embodiment.

The memory element according to the first modification example of the fifth embodiment shows different current-voltage characteristics when a predetermined positive voltage is applied to the upper electrode 20 and when a predetermined negative voltage is applied to the upper electrode 20. In FIG. 17, the solid line indicates a current-voltage characteristic when a predetermined positive voltage is applied to the upper electrode 20, and the dotted line indicates a current-voltage characteristic when a predetermined negative voltage is applied to the upper electrode 20.

When a predetermined positive voltage is applied to the upper electrode 20, the current increases abruptly at the first positive voltage side threshold voltage Vtpp on the positive voltage side. In addition, when a predetermined positive voltage is applied to the upper electrode 20, the current increases abruptly at the first negative voltage side threshold voltage Vtpn on the negative voltage side.

On the other hand, when a predetermined negative voltage is applied to the upper electrode 20, the current increases abruptly at the second positive voltage side threshold voltage Vtnp on the positive voltage side. In addition, when a predetermined negative voltage is applied to the upper electrode 20, the current increases abruptly at the second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is higher than the second negative voltage side threshold voltage Vtnn.

The memory element according to the first modification example of the fifth embodiment can have a high resistance state and a low resistance state on both the positive voltage side and the negative voltage side. When a predetermined positive voltage is applied to the upper electrode 20, a low resistance state is realized on both the positive voltage side and the negative voltage side. On the other hand, when a predetermined negative voltage is applied to the upper electrode 20, a high resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

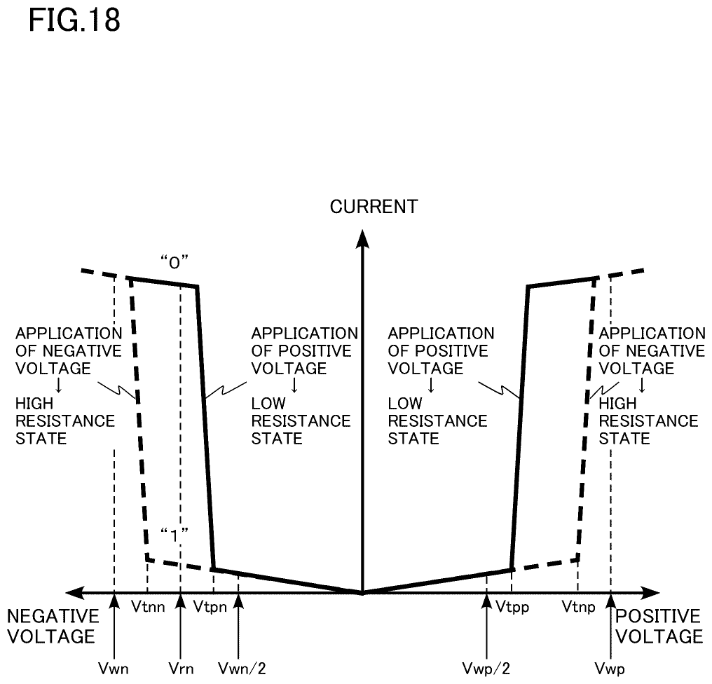

FIG. 18 is an explanatory diagram of a third operation example of the memory operation in the memory device according to the first modification example of the fifth embodiment. FIG. 18 shows a positive side write voltage Vwp, half the positive side write voltage Vwp (Vwp/2), a negative side write voltage Vwn, half the negative side write voltage Vwn (Vwn/2), and a negative side read voltage Vrn when performing a memory operation.

In the third operation example, the high resistance state and the low resistance state on the negative voltage side are used for the memory operation. In the third operation example, the negative side read voltage Vrn is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the negative voltage side, and data “1” is written to the selected cell. When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the negative voltage side, and data “0” is written to the selected cell.

In the third operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the third operation example, when the data of the selected cell is data “1”, the application of the negative side read voltage Vrn does not destroy the data. In other words, in the case of the third operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the third operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

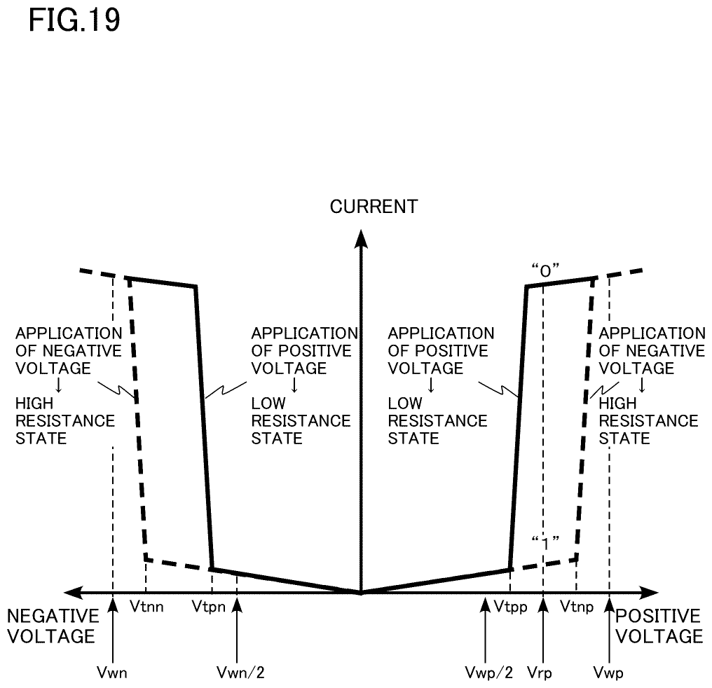

FIG. 19 is an explanatory diagram of a fourth operation example of the memory operation in the memory device according to the first modification example of the fifth embodiment. FIG. 19 shows a positive side write voltage Vwp, half the positive side write voltage Vwp (Vwp/2), a negative side write voltage Vwn, half the negative side write voltage Vwn (Vwn/2), and a positive side read voltage Vrp when performing a memory operation.

In the fourth operation example, the high resistance state and the low resistance state on the positive voltage side are used for the memory operation. In the fourth operation example, the positive side read voltage Vrp is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the positive voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the positive voltage side, and data “0” is written to the selected cell.

In the fourth operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the fourth operation example, regardless of whether the data of the selected cell is data “1” or data “0”, the application of the positive side read voltage Vrp does not destroy the data. In other words, in the case of the fourth operation example, non-destructive reading is possible regardless of whether the data of the selected cell is data “1” or data “0”.

### Second Modification Example

A memory device according to a second modification example of the fifth embodiment is different from the memory device according to the fifth embodiment in that the current-voltage characteristics of the memory elements are different.

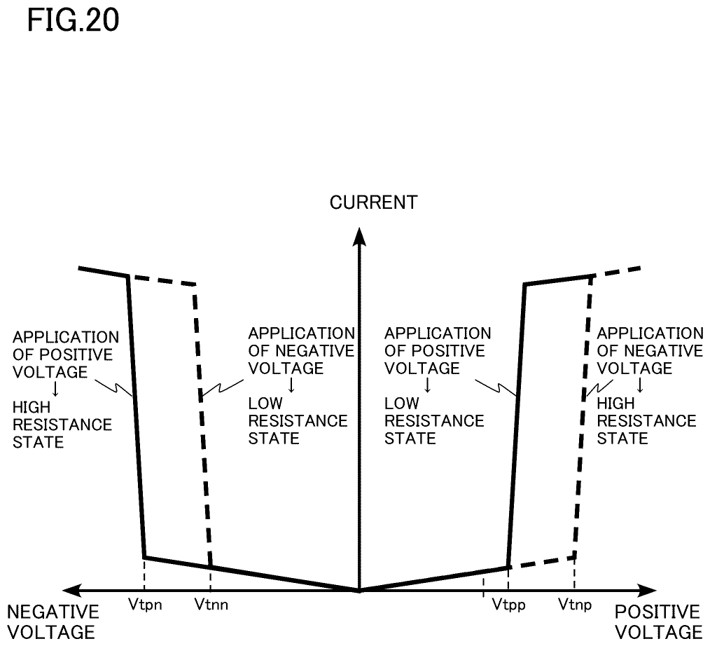

FIG. 20 is an explanatory diagram of the current-voltage characteristic of a memory element according to the second modification example of the fifth embodiment. The horizontal axis indicates a voltage applied to the memory element, and the vertical axis indicates a current flowing through the memory element. In FIG. 20, the horizontal axis indicates a voltage applied to the upper electrode 20 with the electric potential of the lower electrode 10 as a reference. FIG. 20 shows the current-voltage characteristic of the memory layer 60 in the second modification example of the fifth embodiment. FIG. 20 shows the current-voltage characteristic of the memory cell MC in the second modification example of the fifth embodiment.

The memory element according to the second modification example of the fifth embodiment shows different current-voltage characteristics when a predetermined positive voltage is applied to the upper electrode 20 and when a predetermined negative voltage is applied to the upper electrode 20. In FIG. 20, the solid line indicates a current-voltage characteristic when a predetermined positive voltage is applied to the upper electrode 20, and the dotted line indicates a current-voltage characteristic when a predetermined negative voltage is applied to the upper electrode 20.

When a predetermined positive voltage is applied to the upper electrode 20, the current increases abruptly at the first positive voltage side threshold voltage Vtpp on the positive voltage side. In addition, when a predetermined positive voltage is applied to the upper electrode 20, the current increases abruptly at the first negative voltage side threshold voltage Vtpn on the negative voltage side.

On the other hand, when a predetermined negative voltage is applied to the upper electrode 20, the current increases abruptly at the second positive voltage side threshold voltage Vtnp on the positive voltage side. In addition, when a predetermined negative voltage is applied to the upper electrode 20, the current increases abruptly at the second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is lower than the second negative voltage side threshold voltage Vtnn.

The memory element according to the second modification example of the fifth embodiment can have a high resistance state and a low resistance state on both the positive voltage side and the negative voltage side. When a predetermined positive voltage is applied to the upper electrode 20, a low resistance state is realized on the positive voltage side and a high resistance state is realized on the negative voltage side. On the other hand, when a predetermined negative voltage is applied to the upper electrode 20, a high resistance state is realized on the positive voltage side and a low resistance state is realized on the negative voltage side. Hereinafter, the high resistance state will be defined as data “1”, and the low resistance state will be defined as data “0”. The memory cell MC can store 1-bit data of “0” and “1”.

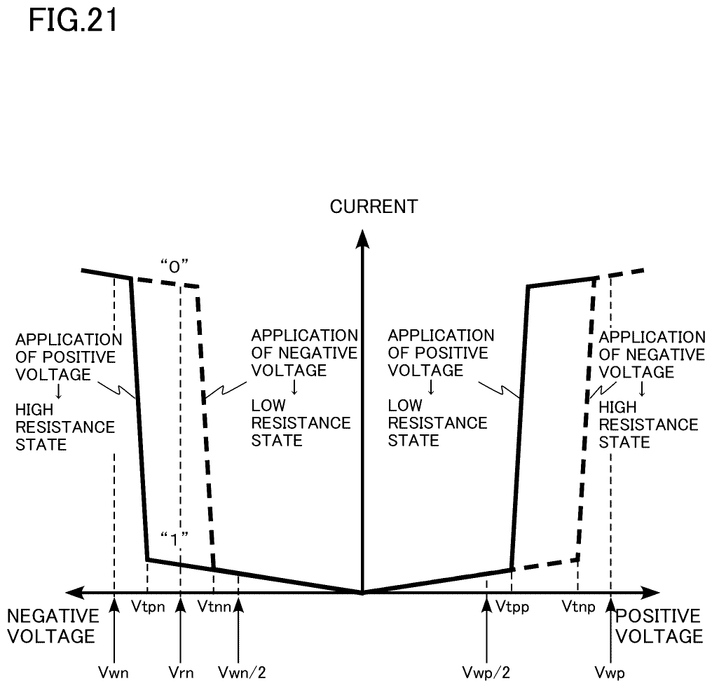

FIG. 21 is an explanatory diagram of a fifth operation example of the memory operation in the memory device according to the second modification example of the fifth embodiment. FIG. 21 shows a positive side write voltage Vwp, half the positive side write voltage Vwp (Vwp/2), a negative side write voltage Vwn, half the negative side write voltage Vwn (Vwn/2), and a negative side read voltage Vrn when performing a memory operation.

In the fifth operation example, the high resistance state and the low resistance state on the negative voltage side are used for the memory operation. In the fifth operation example, the negative side read voltage Vrn is used as a read voltage.

When writing data “1” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a high resistance state is realized on the negative voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the negative voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the fifth operation example, regardless of whether the data of the selected cell is data “1” or data “0”, the application of the negative side read voltage Vrn does not destroy the data.

In other words, in the case of the fifth operation example, non-destructive reading is possible regardless of whether the data of the selected cell is data “1” or data “0”.

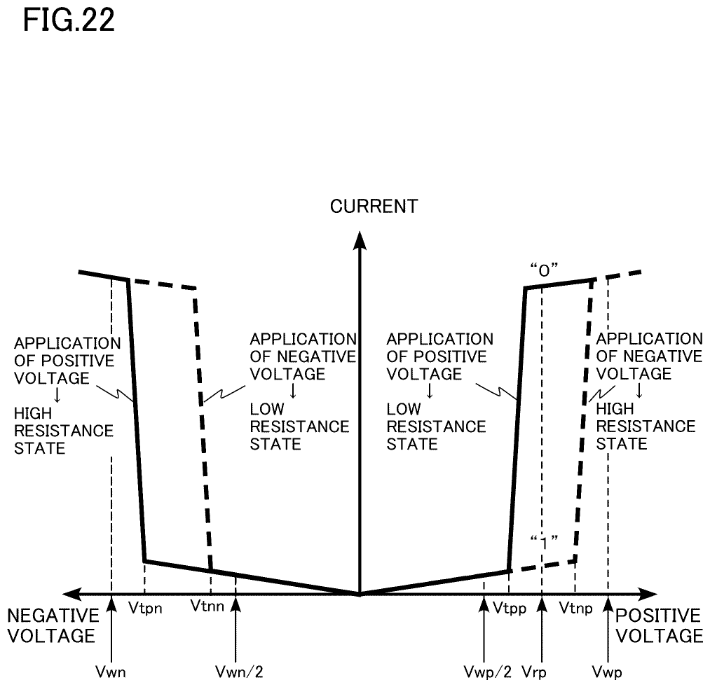

FIG. 22 is an explanatory diagram of a sixth operation example of the memory operation in the memory device according to the second modification example of the fifth embodiment. FIG. 22 shows a positive side write voltage Vwp, half the positive side write voltage Vwp (Vwp/2), a negative side write voltage Vwn, half the negative side write voltage Vwn (Vwn/2), and a positive side read voltage Vrp when performing a memory operation.

In the sixth operation example, the high resistance state and the low resistance state on the positive voltage side are used for the memory operation. In the sixth operation example, the positive side read voltage Vrp is used as a read voltage.

When writing data “1” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a high resistance state is realized on the positive voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the positive voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the sixth operation example, regardless of whether the data of the selected cell is data “1” or data “0”, the application of the positive side read voltage Vrp does not destroy the data. In other words, in the case of the sixth operation example, non-destructive reading is possible regardless of whether the data of the selected cell is data “1” or data “0”.

### Third Modification Example

A memory device according to a third modification example of the fifth embodiment is different from the memory device according to the fifth embodiment in that the current-voltage characteristics of the memory elements are different.

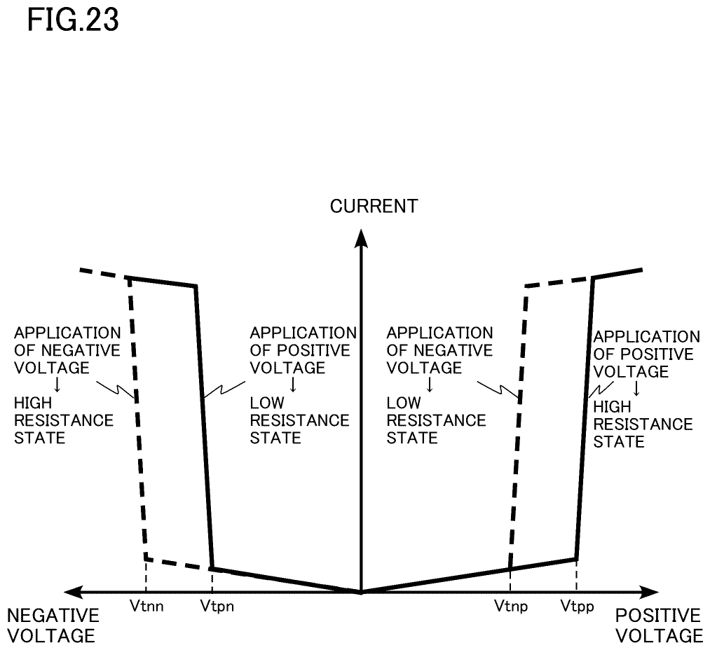

FIG. 23 is an explanatory diagram of the current-voltage characteristic of a memory element according to the third modification example of the fifth embodiment. The horizontal axis indicates a voltage applied to the memory element, and the vertical axis indicates a current flowing through the memory element. In FIG. 23, the horizontal axis indicates a voltage applied to the upper electrode 20 with the electric potential of the lower electrode 10 as a reference. FIG. 23 shows the current-voltage characteristic of the memory layer 60 in the third modification example of the fifth embodiment. FIG. 23 shows the current-voltage characteristic of the memory cell MC in the third modification example of the fifth embodiment.

The memory element according to the third modification example of the fifth embodiment shows different current-voltage characteristics when a predetermined positive voltage is applied to the upper electrode 20 and when a predetermined negative voltage is applied to the upper electrode 20. In FIG. 23, the solid line indicates a current-voltage characteristic when a predetermined positive voltage is applied to the upper electrode 20, and the dotted line indicates a current-voltage characteristic when a predetermined negative voltage is applied to the upper electrode 20.

When a predetermined positive voltage is applied to the upper electrode 20, the current increases abruptly at the first positive voltage side threshold voltage Vtpp on the positive voltage side. In addition, when a predetermined positive voltage is applied to the upper electrode 20, the current increases abruptly at the first negative voltage side threshold voltage Vtpn on the negative voltage side.

On the other hand, when a predetermined negative voltage is applied to the upper electrode 20, the current increases abruptly at the second positive voltage side threshold voltage Vtnp on the positive voltage side. In addition, when a predetermined negative voltage is applied to the upper electrode 20, the current increases abruptly at the second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is higher than the second negative voltage side threshold voltage Vtnn.

The memory element according to the third modification example of the fifth embodiment can have a high resistance state and a low resistance state on both the positive voltage side and the negative voltage side. When a predetermined positive voltage is applied to the upper electrode 20, a high resistance state is realized on the positive voltage side and a low resistance state is realized on the negative voltage side. On the other hand, when a predetermined negative voltage is applied to the upper electrode 20, a low resistance state is realized on the positive voltage side and a high resistance state is realized on the negative voltage side. Hereinafter, the high resistance state is defined as data “1”, and the low resistance state is defined as data “0”. The memory cell MC can store 1-bit data of “0” and “1”.

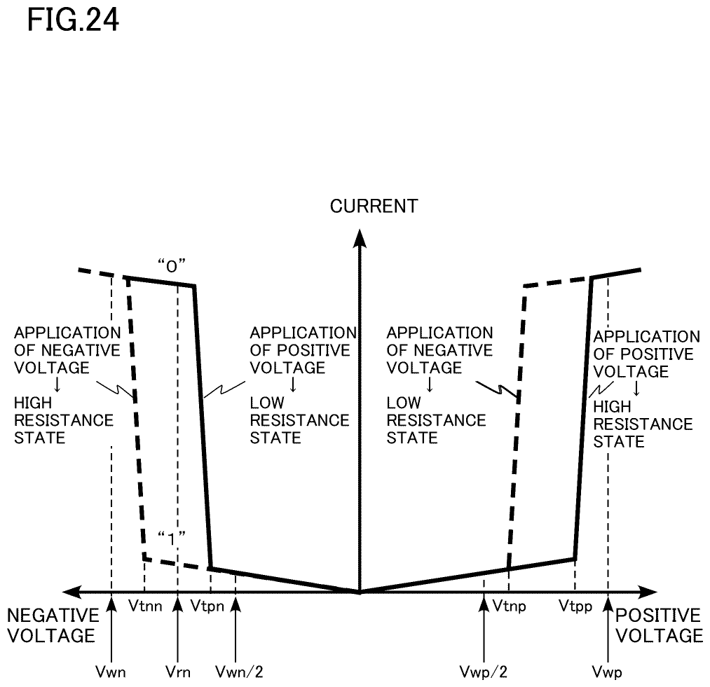

FIG. 24 is an explanatory diagram of a seventh operation example of the memory operation in the memory device according to the third modification example of the fifth embodiment. FIG. 24 shows a positive side write voltage Vwp, half the positive side write voltage Vwp (Vwp/2), a negative side write voltage Vwn, half the negative side write voltage Vwn (Vwn/2), and a negative side read voltage Vrn when performing a memory operation.

In the seventh operation example, the high resistance state and the low resistance state on the negative voltage side are used for the memory operation. In the seventh operation example, the negative side read voltage Vrn is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the negative voltage side, and data “1” is written to the selected cell.

When writing data “0” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a low resistance state is realized on the negative voltage side, and data “0” is written to the selected cell.

In the seventh operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, in the seventh operation example, when writing data “0” to the selected cell, assuming that the data stored in the selected cell is data “1”, a current flows if the positive side write voltage Vwp is higher than the second positive voltage side threshold voltage Vtnp even if the positive side write voltage Vwp is lower than the first positive voltage side threshold voltage Vtpp. For this reason, data “0” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the seventh operation example, when the data of the selected cell is data “1”, the application of the negative side read voltage Vrn does not destroy the data. In other words, in the case of the seventh operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the seventh operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

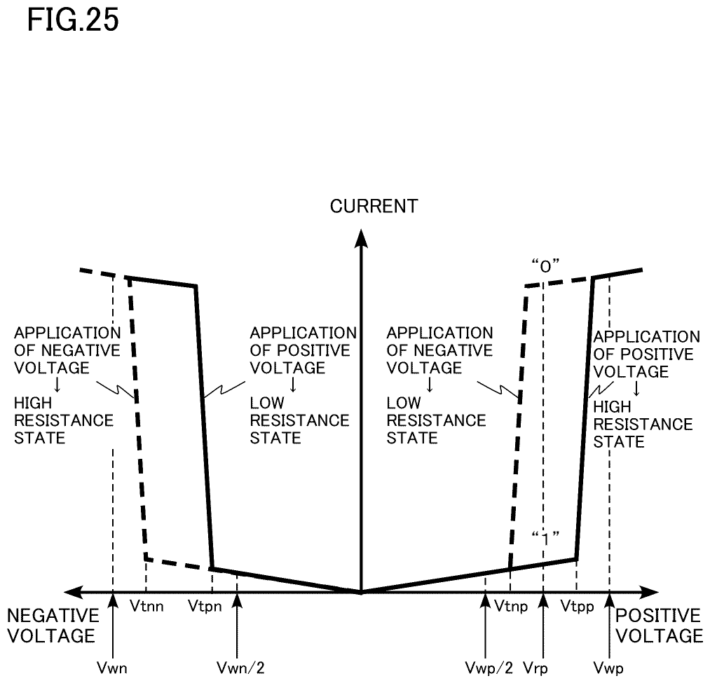

FIG. 25 is an explanatory diagram of an eighth operation example of the memory operation in the memory device according to the third modification example of the fifth embodiment. FIG. 25 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the eighth operation example, the high resistance state and the low resistance state on the positive voltage side are used for the memory operation. In the eighth operation example, the positive side read voltage Vrp is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the positive voltage side, and data “1” is written to the selected cell.

When writing data “0” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a low resistance state is realized on the positive voltage side, and data “0” is written to the selected cell.

In the eighth operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, in the eighth operation example, when writing data “0” to the selected cell, assuming that the data stored in the selected cell is data “1”, a current flows if the negative side write voltage Vwn is lower than the first negative voltage side threshold voltage Vtpn even if the negative side write voltage Vwn is higher than the second negative voltage side threshold voltage Vtnn. For this reason, data “0” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the eighth operation example, when the data of the selected cell is data “1”, the application of the positive side read voltage Vrp does not destroy the data. In other words, in the case of the eighth operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the eighth operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

In the memory devices according to the fifth embodiment and its modification examples, the memory element of the memory cell MC has a switching function and an information storage function. The memory layer 60 is a single layer and realizes the function of the switching layer 40 and the function of the variable resistance layer 50 in the first to fourth embodiments. Since the memory layer 60 in the fifth embodiment is a single layer and has a switching function and a memory function, the structure of the memory cell MC can be made very simple.

In addition, the memory layer 60 of each memory device according to the fifth embodiment and its modification examples has the same configuration as the switching layer 40 in the first to fourth embodiments. Therefore, according to the fifth embodiment and its modification examples, as in the first to fourth embodiments, it is possible to realize a memory device having excellent switching characteristics such as a low half-select leakage current and high reliability.

In addition, the plurality of current-voltage characteristics of the memory elements shown in the fifth embodiment and its modification examples can be realized, for example, by adopting the memory layer 60 having an appropriate chemical composition.

Although the magnetoresistive memory has been described as an example of the two-terminal memory device in the first to third embodiments and the resistive memory has been described as an example of the memory device in the fourth embodiment, embodiments can be applied to other two-terminal memory devices. For example, embodiments can be applied to a phase change memory (PCM) or a ferroelectric random access memory (FeRAM).

While certain embodiments have been described, these embodiments have been presented by way of example only, and are not intended to limit the scope of the inventions. Indeed, the memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A memory device, comprising:
a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer,
wherein the switching layer contains an oxide of a first element, and a compound of a second element and a third element, the first element being at least one element selected from a group consisting of silicon (Si), boron (B), germanium (Ge), phosphorus (P), and arsenic (As), the second element being at least one element selected from a group consisting of zinc (Zn), tin (Sn), gallium (Ga), indium (In), and bismuth (Bi), and the third element being at least one element selected from a group consisting of tellurium (Te), sulfur (S), and selenium (Se), and
a first ratio of a sum of atomic concentrations of the first element and oxygen (O) to a sum of atomic concentrations of the first element, the second element, the third element, and oxygen (O) in the switching layer is equal to or more than 10%.

2. The memory device according to claim 1,
wherein the first ratio is equal to or more than 20%.

3. The memory device according to claim 1,
wherein the first ratio is equal to or more than 40%.

4. The memory device according to claim 1,
wherein the first ratio is equal to or more than 55%.

5. The memory device according to claim 1,
wherein the switching layer further contains a fourth element, the fourth element being at least one element selected from a group consisting of lithium (Li), sodium (Na), potassium (K), magnesium (Mg), calcium (Ca), barium (Ba), lead (Pb), aluminum (Al), vanadium (V), iron (Fe), and tungsten (W).

6. The memory device according to claim 1,
wherein the sum of the atomic concentrations of the first element, the second element, the third element, and oxygen (O) in the switching layer is equal to or more than 90%.

7. The memory device according to claim 1,
wherein the first conductive layer, the second conductive layer, or the third conductive layer contains at least one material selected from a group consisting of carbon, carbon nitride, tungsten, tungsten carbide, tungsten nitride, titanium, titanium nitride, tantalum, tantalum carbide, and tantalum nitride.

8. The memory device according to claim 1,
wherein the first conductive layer includes a first layer and a second layer provided between the switching layer and the first layer and in contact with the switching layer,
the first layer contains carbon, carbon nitride, or tungsten carbide, and
the second layer contains tungsten, tungsten nitride, titanium, titanium nitride, tantalum, or tantalum nitride.

9. The memory device according to claim 1,
wherein the third conductive layer includes a first layer and a second layer provided between the switching layer and the first layer and in contact with the switching layer,
the first layer contains carbon, carbon nitride, or tungsten carbide, and
the second layer contains tungsten, tungsten nitride, titanium, titanium nitride, tantalum, or tantalum nitride.

10. The memory device according to claim 1,
wherein the switching layer includes a first region, a second region, and a third region in a cross section parallel to a first direction connecting the first conductive layer and the second conductive layer, and the first region is provided between the second region and the third region in a second direction perpendicular to the first direction in the cross section,
the first region contains or does not contain fluorine (F), and the second region and the third region contain fluorine (F), and
an atomic concentration of fluorine (F) in the second region and the third region is higher than an atomic concentration of fluorine in the first region.

11. The memory device according to claim 10,
wherein an atomic concentration of the second element in the second region and the third region is higher than an atomic concentration of the second element in the first region.

12. The memory device according to claim 1,
wherein the switching layer includes a first region, a second region, and a third region in a cross section parallel to a first direction connecting the first conductive layer and the second conductive layer, and the first region is provided between the second region and the third region in a second direction perpendicular to the first direction in the cross section,
an atomic concentration of the second element in the second region and the third region is lower than an atomic concentration of the second element in the first region, and
an atomic concentration of the third element in the second region and the third region is lower than an atomic concentration of the third element in the first region.

13. The memory device according to claim 1,
wherein a second ratio of an atomic concentration of the second element to an atomic concentration of the third element is equal to or more than 50% and equal to or less than 200%.

14. The memory device according to claim 1,
wherein the variable resistance layer includes a magnetic tunnel junction.

15. The memory device according to claim 1,
wherein the variable resistance layer has an electrical resistance changing with application of a predetermined voltage, and
the switching layer has a nonlinear current-voltage characteristic that a current increases at a specific threshold voltage.

16. The memory device according to claim 1, further comprising:
a plurality of first wirings; and
a plurality of second wirings crossing the plurality of first wirings,
wherein the memory cell is provided in a region where one of the plurality of first wirings and one of the plurality of second wirings cross each other.

17. A memory device, comprising:
a memory cell including a first conductive layer, a second conductive layer, and a memory layer provided between the first conductive layer and the second conductive layer,
wherein the memory layer contains an oxide of a first element, and a compound of a second element and a third element, the first element being at least one element selected from a group consisting of silicon (Si), boron (B), germanium (Ge), phosphorus (P), and arsenic (As), the second element being at least one element selected from a group consisting of zinc (Zn), tin (Sn), gallium (Ga), indium (In), and bismuth (Bi), and the third element being at least one element selected from a group consisting of tellurium (Te), sulfur (S), and selenium (Se), and
a first ratio of a sum of atomic concentrations of the first element and oxygen (O) to a sum of atomic concentrations of the first element, the second element, the third element, and oxygen (O) in the memory layer is equal to or more than 10%.

18. The memory device according to claim 17,
wherein the first ratio is equal to or more than 20%.

19. The memory device according to claim 17,
wherein the first ratio is equal to or more than 40%.

20. The memory device according to claim 17,
wherein the first ratio is equal to or more than 55%.

21. The memory device according to claim 17,
wherein the memory layer further contains a fourth element, the fourth element being at least one element selected from a group consisting of lithium (Li), sodium (Na), potassium (K), magnesium (Mg), calcium (Ca), barium (Ba), lead (Pb), aluminum (Al), vanadium (V), iron (Fe), and tungsten (W).

22. The memory device according to claim 17,
wherein the sum of the atomic concentrations of the first element, the second element, the third element, and oxygen (O) in the memory layer is equal to or more than 90%.

23. The memory device according to claim 17,
wherein the first conductive layer or the second conductive layer contains at least one material selected from a group consisting of carbon, carbon nitride, tungsten, tungsten carbide, tungsten nitride, titanium, titanium nitride, tantalum, tantalum carbide, and tantalum nitride.

24. The memory device according to claim 17,
wherein the first conductive layer includes a first layer and a second layer provided between the memory layer and the first layer and in contact with the memory layer,
the first layer contains carbon, carbon nitride, or tungsten carbide, and
the second layer contains tungsten, tungsten nitride, titanium, titanium nitride, tantalum, or tantalum nitride.

25. The memory device according to claim 17,
wherein the second conductive layer includes a first layer and a second layer provided between the memory layer and the first layer and in contact with the memory layer,
the first layer contains carbon, carbon nitride, or tungsten carbide, and
the second layer contains tungsten, tungsten nitride, titanium, titanium nitride, tantalum, or tantalum nitride.

26. The memory device according to claim 17,
wherein the memory layer includes a first region, a second region, and a third region in a cross section parallel to a first direction connecting the first conductive layer and the second conductive layer, and the first region is provided between the second region and the third region in a second direction perpendicular to the first direction in the cross section,
the first region contains or does not contain fluorine (F), and the second region and the third region contain fluorine (F), and
an atomic concentration of fluorine (F) in the second region and the third region is higher than an atomic concentration of fluorine in the first region.

27. The memory device according to claim 26,
wherein an atomic concentration of the second element in the second region and the third region is higher than an atomic concentration of the second element in the first region.

28. The memory device according to claim 17,
wherein the memory layer includes a first region, a second region, and a third region in a cross section parallel to a first direction connecting the first conductive layer and the second conductive layer, and the first region is provided between the second region and the third region in a second direction perpendicular to the first direction in the cross section,
an atomic concentration of the second element in the second region and the third region is lower than an atomic concentration of the second element in the first region, and
an atomic concentration of the third element in the second region and the third region is lower than an atomic concentration of the third element in the first region.

29. The memory device according to claim 17,
wherein a second ratio of an atomic concentration of the second element to an atomic concentration of the third element is equal to or more than 50% and equal to or less than 200%.

30. The memory device according to claim 17,
wherein the memory layer has a nonlinear current-voltage characteristic that a current increases at a specific threshold voltage, and the threshold voltage changes with application of a predetermined voltage.

31. The memory device according to claim 17, further comprising:
a plurality of first wirings; and
a plurality of second wirings crossing the plurality of first wirings,
wherein the memory cell is provided in a region where one of the plurality of first wirings and one of the plurality of second wirings cross each other.
